(19) United States
(12) Patent Application Publication
(10) Pub. No.: US 2026/0164968 A1
(43) Pub. Date: Jun. 11, 2026

(54) DISPLAY PANEL

(71) Applicant: LG Display Co., Ltd., Seoul (KR)

(72) Inventor: Mi Hee SHIN, Paju-si (KR)

(73) Assignee: LG Display Co., Ltd., Seoul (KR)

(21) Appl. No.: 19/376,510

(22) Filed: Oct. 31, 2025

(30) Foreign Application Priority Data
Dec. 11, 2024 (KR) 10-2024-0183670

(51) Int. Cl. H10K 59/131; H10K 59/35

(52) U.S. Cl. CPC H10K 59/131; H10K 59/353

(57) ABSTRACT

A display panel cam include a substrate having a first active area with an emission area, a first transmission part, and a second transmission part, and a second active area surrounding the first active area. The display panel can further include a luminous element disposed on the substrate and including a first electrode overlapping the emission area and a second electrode facing the first electrode, and a signal line disposed between the first transmission part and the second transmission part. The first transmission part can have a higher transmittance than the second transmission part.

### CROSS-REFERENCE TO RELATED APPLICATION

This application claims priority to Korean Patent Application No. 10-2024-0183670, filed in the Republic of Korea on Dec. 11, 2024, the disclosure of which is hereby expressly incorporated by reference in its entirety.

### BACKGROUND

### Field of the Invention

The present disclosure relates to a display panel, and more particularly, to a display panel capable of improving a point spread function (PSF) of a transmission part.

### Discussion of the Related Art

The arrival of a full-fledged information age has led to the development of the field of display devices that visually display electrical information signals. Accordingly, research for developing performance such as thickness reduction, weight reduction, and power consumption reduction is underway for various display apparatuses.

Specific examples of display apparatuses include a liquid crystal display (LCD) apparatus, an organic light emitting display (OLED) apparatus, a quantum dot (QD) display apparatus, and the like.

Multimedia functions of mobile terminals have improved in recent years. For example, an OLED apparatus with a built-in optoelectronic device on a top surface thereof has been developed.

A full-screen design is being proposed for a camera part and sensor parts located on a display part, which is a top surface of a display apparatus, so that it is not visible to users for the sake of aesthetics. To this end, a pixel part and a transmission part are placed together on the camera part and various sensor parts, thereby improving a recognition rate of sensors and aesthetics for the users.

Further, a design for maximizing transmittance is applied to a camera part and various sensor parts of a display panel to improve a recognition rate.

### SUMMARY OF THE DISCLOSURE

Transmittance of a transmission part can be improved by patterning a metal disposed on an upper end of a luminous element in a camera part and various sensor parts of a display panel. As the transmittance is improved, lines can be exposed between portions of the patterned metal in the transmission part. The exposed lines can cause diffraction of signals such as light entering from outside the display panel.

The diffracted light can be expressed using a point spread function (PSF). At this time, sensors can be designed to react with a zeroth-order signal with the highest light intensity in the PSF for the diffracted light. However, the image resolution of the sensors can be reduced as the zeroth-order light intensity of the PSF decreases due to the lines exposed between the portions of the patterned metal.

Thus, in a display panel according to one or more embodiments of the present disclosure, the zeroth-order light intensity of the PSF can be improved by minimizing a patterned configuration on a pixel part without disposing a metal or lines on a transmission part. Accordingly, the present disclosure can provide a display panel with an improved PSF.

Another object of the present disclosure is to provide an improved display panel which address the limitations associated with the related art.

Objectives of the present disclosure are not limited to the above-mentioned objectives, and other unmentioned objectives should be clearly understood by those of ordinary skill in the art to which the technical spirit of the present disclosure pertains from the description below.

A display panel according to one or more embodiments of the present disclosure can include a substrate including a first active area including an emission area, a first transmission part, and a second transmission part and a second active area surrounding the first active area, a luminous element disposed on the substrate and including a first electrode overlapping the emission area and a second electrode facing the first electrode, and a signal line disposed between the first transmission part and the second transmission part, wherein the first transmission part has a higher transmittance than the second transmission part.

A display panel according to one or more embodiments of the present disclosure can include a first active area including a first pixel part, a transmission pattern area, and a first driving circuit part disposed in the first pixel part while spaced from the transmission pattern area; a second active area surrounding the first active area and including a second pixel part and a second driving circuit part disposed in the second pixel part; and a substrate including the first and second active areas, wherein the first driving circuit part and the second driving circuit part each include a plurality of transistors disposed on the substrate, and the transistors disposed in the first driving circuit part are fewer in number than the transistors disposed in the second driving circuit part.

A display panel according to one or more embodiments of the present disclosure can include a substrate including a first active area including an emission area and a first transmission part, and a second active area surrounding the first active area; a luminous element disposed on the substrate and including a first electrode overlapping the emission area and a second electrode facing the first electrode; and a driving circuit part for driving the luminous element, wherein the second electrode and the driving circuit part do not overlap with the first transmission part.

### BRIEF DESCRIPTION OF THE DRAWINGS

The above and other objects, features, and advantages of the present disclosure will become more apparent to those of ordinary skill in the art by describing example embodiments thereof in detail with reference to the accompanying drawings, in which:

FIG. 1 is a plan view of a display panel according to one or more embodiments of the present disclosure;

FIG. 2 is a plan view of a first active area and a second active area of a display panel according to one or more embodiments of the present disclosure;

FIG. 3A is an enlarged view of a partial region of the second active area of FIG. 2 according to an example of the present disclosure;

FIG. 3B shows cross-sectional views along lines V-1-V-1′ and V-2-V-2′ of FIG. 3A according to an example of the present disclosure;

FIG. 4 is a plan view of a display panel according to a first embodiments of the present disclosure;

FIG. 5 is a cross-sectional view along line I-I′ of FIG. 4 according to an example of the present disclosure;

FIGS. 6A and 6B are cross-sectional views of emission areas of FIG. 4 according to an example of the present disclosure;

FIGS. 7A to 7D are plan views of display panels according to second to fifth embodiments of the present disclosure;

FIG. 8 is a cross-sectional view along line II-II′ of FIG. 7A according to an example of the present disclosure;

FIGS. 9A to 9C are plan views of display panels according to sixth to eighth embodiments of the present disclosure;

FIG. 10A is plan views of a display panel according to a ninth embodiment of the present disclosure;

FIG. 10B is modified example of FIG. 10A;

FIG. 11 shows cross-sectional views along lines III-III′ and IV-IV′ of FIG. 10A according to an example of the present disclosure;

FIGS. 12A and 12B are plan views of a display panel according to a tenth embodiment of the present disclosure;

FIG. 13 is a plan view of a display panel according to an eleventh embodiment of the present disclosure;

FIG. 14 is a PSF graph relating to the presence/absence of spacers;

FIGS. 15A to 15F are process views of FIG. 11 according to an example of the present disclosure; and

FIG. 16 is a plan view of a display panel according to a twelfth embodiment of the present disclosure.

### DETAILED DESCRIPTION OF THE EMBODIMENTS

Advantages and features of the present disclosure and methods of achieving them will be apparent with reference to the embodiments described below in detail with the accompanying drawings. However, the present disclosure is not limited to the embodiments disclosed below and can be implemented in various different forms, the present embodiments only make the disclosure of the present specification complete and are provided to fully inform those of ordinary skill in the art to which the present disclosure pertains of the scope of the disclosure.

The shapes, sizes, proportions, angles, numbers, and the like disclosed in the drawings for explaining the embodiments of the present disclosure are illustrative, and the present disclosure is not limited to the illustrated matters. In addition, in describing the present disclosure, if it is determined that detailed description of a related known technology can unnecessarily obscure the gist of the present disclosure, the detailed description thereof will be omitted.

When terms such as “including,” “having,” “consisting of,” and the like are used in this disclosure, other parts can be added unless “only” is used. When a component is expressed in a singular form, a plurality of components can be included unless otherwise specified.

In construing a component, the component is construed as including an error or tolerance range even when there is no separate explicit description thereof.

In describing a position relationship, for example, when a position relation between two parts is described as, for example, “on,” “over,” “under,” or “next to,” one or more other parts can be located between the two parts unless “immediately” or “directly” is used.

When an element or layer is referred to as being on another element or layer, the element or layer can be directly on the other element or layer, or other layers or other elements can be interposed therebetween.

In addition, the terms such as “first,” “second,” and the like can be used herein to describe various components, but the components are not limited by these terms. These terms are only used to distinguish one component from another and may not define order or sequence. Therefore, a first component mentioned below could be termed a second component within the technical spirit of the present disclosure.

Like reference numerals refer to like components throughout. Further, the term “can” fully encompasses all the meanings and coverages of the term “may” and vice versa.

The size and thickness of each configuration shown in the drawings are illustrated for convenience of description, and the present disclosure is not necessarily limited to the sizes and thicknesses of configurations illustrated herein.

The features of various embodiments of the present disclosure can be partially or entirely adhered to or combined with each other and can be interlocked and operated in technically various ways, and the embodiments can be carried out independently of or in association with each other.

In the present disclosure, examples of “apparatus” can include a display apparatus such as a liquid crystal module (LCM) or an OLED module that includes a display panel and a driver for driving the display panel. In addition, examples of the apparatus can include a set electronic apparatus or a set apparatus such as a notebook computer, a television (TV), a computer monitor, an automotive display or another type of equipment display for vehicles, or a mobile electronic apparatus such as a smartphone or an electronic pad, which is a complete product (or a final product) including an LCM or an OLED module.

Therefore, in the present disclosure, examples of a display apparatus can include a display apparatus itself, such as an LCM or an OLED module, and a set apparatus which is an application product or a final consumer apparatus including the LCM or the OLED module.

In addition, in some embodiments of the present disclosure, an LCM or an OLED module including a display panel and a driver can be referred to as a “display apparatus,” and an electronic apparatus that is a final product including an LCM or an OLED module can be referred to as a “set apparatus.” For example, the display apparatus can include a display panel, such as an LCD or an OLED, and a source printed circuit board (PCB) that is a controller for driving the display panel. The set apparatus can further include a set PCB that is a set controller electrically connected to the source PCB to perform overall control of the set apparatus.

Examples of a display panel used in one or more embodiments of the present disclosure can include any type of display panel, such as a liquid crystal display panel, an organic light-emitting diode (OLED) display panel, and an electroluminescent display panel, but are not limited thereto.

Hereinafter, various embodiments of the present disclosure will be described in detail with reference to the accompanying drawings. All the components of each display panel/device/apparatus according to all embodiments of the present disclosure are operatively coupled and configured. Further, scales of components illustrated in the drawings are different from the real scales for the convenience of description, and thus the scales are not limited to those illustrated in the drawings.

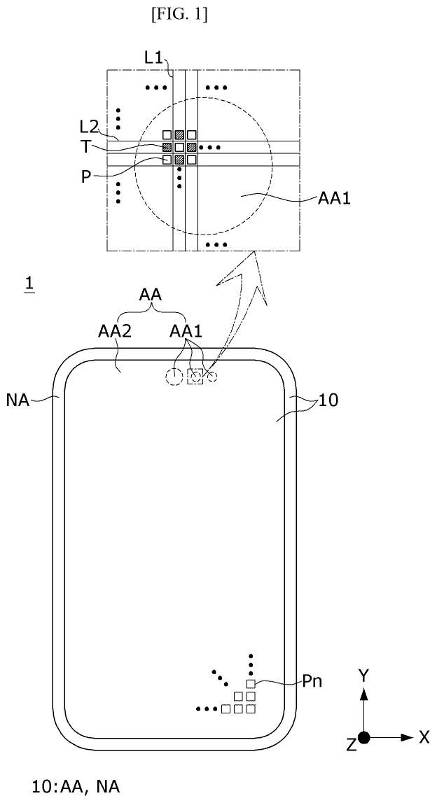

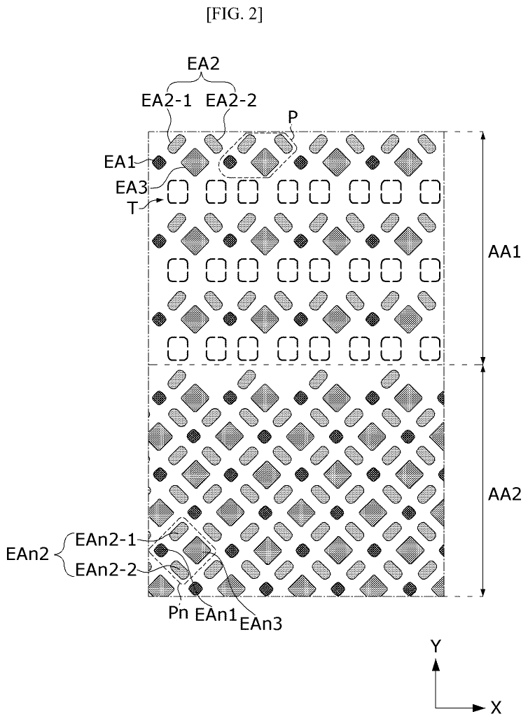

FIG. 1 is a schematic plan view of a display panel according to one or more embodiments of the present disclosure. FIG. 2 is a schematic plan view showing a first active area and a second active area of a display panel or display device according to one or more embodiments of the present disclosure.

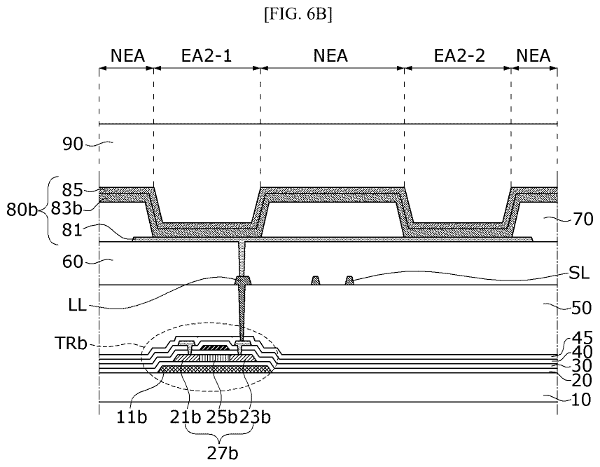

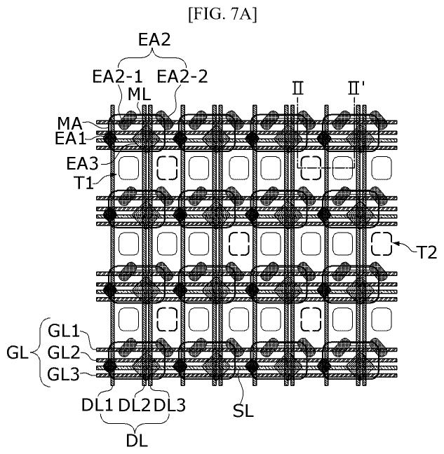

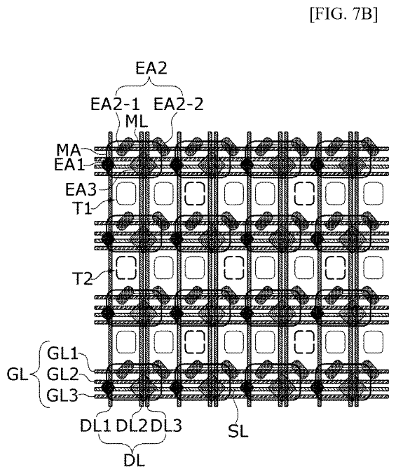

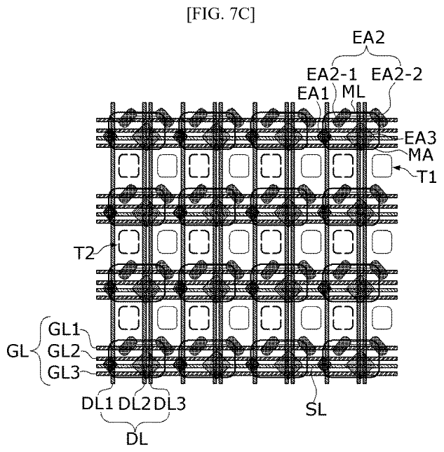

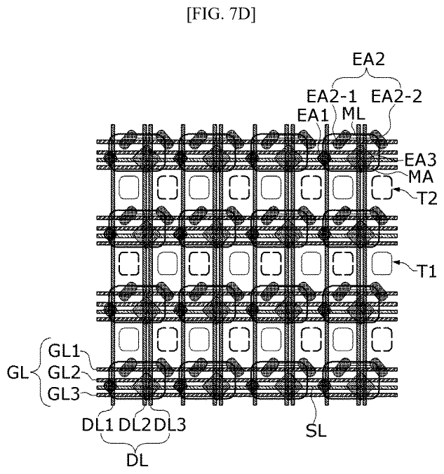

Referring to FIGS. 1 and 2, a display panel 1 according to one embodiment of the present specification can include a substrate 10 including a first active area AA1 including an emission area EA (shown as EA1, EA2 and EA3 in FIG. 2) and a transmission part T and a second active area AA2 surrounding the first active area AA1, luminous elements 80a, 80b, and 80c (see FIG. 6A and FIG. 6B) disposed on the substrate 10 and including a first electrode 81 (see FIG. 6A) overlapping the emission area EA and a second electrode 85 (see FIG. 6A) facing the first electrode 81, and signal lines L1 and L2 disposed between transmission parts T, for example, between a first transmission part T1 and a second transmission part T2 (see for example, FIGS. 7A-7D″), wherein the first transmission part T1 can have a higher transmittance than the second transmission part T2.

A row direction X and a column direction Y of the display panel 1 can be a longitudinal direction (the horizontal direction of FIG. 1) and a width direction (the vertical direction of FIG. 1), respectively, of the display panel 1. A thickness direction can be a direction perpendicular to a plane having the row direction X and the column direction Y of the display panel 1. In addition, the display panel 1 can have a cross-section in the thickness direction.

The substrate 10 can include an active area AA and a non-active area NA around the active area AA. The active area AA can be an area where a screen shows, and the non-active area NA can be an area where the screen does not show.

The active area AA can include a first active area AA1 and a second active area AA2 surrounding the first active area AA1. The first active area AA1 and the second active area AA2 can both display a screen and have a plurality of pixel parts P and Pn disposed thereon. Here, the first active area AA1 can further include the transmission part T disposed between the pixel parts P.

In some cases, a plurality of first pixel parts P disposed in the first active area AA1 and a plurality of second pixel parts Pn disposed in the second active area AA2 can have different alignment structures from each other. In addition, structures of emission areas EA (shown as EA1, EA2 and EA3 in FIG. 2) and EAn (shown as EAn1, EAn2 and EAn3 in FIG. 2) in the first and second pixel parts P and Pn can be different from each other.

The first active area AA1 can be provided as a plurality of first active areas AA1. The plurality of first active areas AA1 can each include an optoelectronic device. The optoelectronic device can include a light reception device receiving light such as a camera or a sensor. However, the display panel 1 of the present disclosure is not limited thereto. For example, one can be an area in which a camera is embedded, and the other can be an area in which an infrared (IR) sensor is embedded. Although the first active area AA1 is illustrated as being disposed in an upper center area in one embodiment according to the present disclosure, the first active area AA1 is not limited thereto. For example, the first active area AA1 can be disposed in an upper left area or an upper right area.

The display panel 1 of the present disclosure according to one embodiment can include a plurality of signal lines L1 and L2 formed across the first and second active areas AA1 and AA2. The plurality of signal lines L1 and L2 can include a camera or a sensor disposed in the first active area AA1 and lines for transmitting signals to the first pixel parts P.

The signal line L1 formed in the column direction Y can be provided as one or more signal lines L1 disposed between the first pixel parts P or transmission parts T disposed in the row direction X. For example, the signal line L1 formed in the column direction Y can be various signal lines such as a signal line connected to a camera or a sensor, a data line or a gate line, and a power voltage line.

The signal line L2 formed in the row direction X can be provided as one or more signal lines L2 disposed between the transmission parts T adjacent to each other in the column direction Y. For example, the signal line L2 formed in the row direction X can be various signal lines such as a signal line connected to a camera or a sensor, a data line or a gate line, and a power voltage line.

A portion of the signal line L2 formed in the row direction X can be disposed to overlap the first pixel parts P. When the first pixel parts P are repeatedly disposed in the row direction X and the transmission parts T are disposed between the first pixel parts P adjacent to each other in the column direction Y, the signal line L2 formed in the row direction X can be formed across the first pixel parts P. This will be described in detail below in the following embodiment.

The first active area AA1 can have a plurality of first pixel parts P and a plurality of transmission parts T repeatedly disposed therein. Referring to FIG. 2, the plurality of first pixel parts P disposed in the first active area AA1 can be disposed side by side in each of the row direction X and the column direction Y, and a separation distance can be greater in the column direction Y than in the row direction X. For example, the plurality of first pixel parts P disposed in the first active area AA1 can have a transmission part T disposed between the first pixel parts P adjacent in the column direction Y.

The plurality of transmission parts T can be disposed apart from each other between the first pixel parts P adjacent to each other in the column direction Y. In other words, the plurality of transmission parts T can be disposed side by side in the row direction X between an arbitrary first row, in which the first pixel parts P are disposed side by side, and a second row adjacent to the first row.

The plurality of transmission parts T can be disposed apart from each other with one or more signal lines L1 (see FIG. 1) disposed therebetween in the row direction X. In other words, at least one signal line L1 can be disposed on a boundary part, which is an area between the transmission parts T adjacent to each other. Although an example in which one or more data lines DL are disposed between the transmission parts T adjacent to each other will be described below in the following embodiment, the present disclosure is not limited thereto.

In a structure between the first active area AA1 and the second active area AA2, the structure of the first active area AA1 is not limited to that shown in FIGS. 1 and 2. For example, the first active area AA1 is not limited to that illustrated in FIGS. 1 and 2 and can have transmission parts having different transmittances (for example, transmission parts T1 and T2 of FIGS. 7A-7D) disposed between the first pixel parts P. The arrangement structure of the plurality of first pixel parts P and the plurality of transmission parts T will be described in detail below in the following embodiment.

The second active area AA2 can be a normal area that occupies a great portion of the screen. The second active area AA2 can have a plurality of second pixel parts Pn repeatedly disposed therein. The number of second pixel parts Pn disposed per unit area of the second active area AA2 can be greater than the number of first pixel parts P disposed per unit area of the first active area AA1.

The plurality of second pixel parts Pn can constitute an alignment structure in which second pixel parts Pn are disposed in each of the row direction X, the column direction Y, and a diagonal direction (for example, an X=Y-axis direction) relative to one second pixel part Pn. However, the alignment structure of the plurality of second pixel parts Pn of the display panel 1 of the present disclosure is not limited to that illustrated in FIG. 2. For example, the plurality of second pixel parts Pn can be arranged in a matrix type lattice structure in which they intersect each other.

The first and second pixel parts P and Pn can each be a unit pixel including emission areas EA and EAn of different colors. For example, the first and second pixel parts P and Pn can each further include a non-emission area NEA. The first and second pixel parts P and Pn can each be made of emission areas EA and EAn that are areas in which light is actually emitted and non-emission areas that are areas disposed around the emission areas EA and EAn and in which light is not emitted. The emission areas EA and EAn can each be defined by a gate line GL and a data line DL formed in a matrix form to intersect each other on the substrate 10.

The arrangement structure of the emission areas EA of the first pixel parts P and the arrangement structure of the emission areas EAn of the second pixel parts Pn can be different from each other.

In either arrangement structure, the first and second pixel parts P and Pn can each include first and first-n emission areas EA1 and EAn1, second and second-n emission areas EA2 and EAn2, and third and third-n emission areas EA3 and EAn3 of different colors. However, the display panel 1 of the present disclosure is not limited thereto. For example, in order to overcome a resolution difference between the first active area AA1 and the second active area AA2, the first and second pixel parts P and Pn can each include emission areas that emit light of different colors. An example in which the emission areas EA and EAn emit light of the same color to more clearly show a difference between the first and second pixel parts P and Pn will be described in the present disclosure.

The first and first-n emission areas EA1 and EAn1 can emit red light, the second and second-n emission areas EA2 and EAn2 can emit green light, and the third and third-n emission areas EA3 and EAn3 can emit blue light. Here, the second emission area EA2 can include second-first and second-second emission areas EA2-1 and EA2-2, and the second-n emission area EAn2 can include second-first-n and second-second-n emission areas EAn2-1 and EAn2-2.

The display panel 1 of the present disclosure can have a red-green-blue-green (RGBG) PenTile pixel structure. The PenTile pixel structure can allow more emission areas emitting light of a specific color to be disposed than a general red-green-blue (RGB) arrangement structure. The Pen Tile pixel structure can increase the sharpness and resolution of a screen while decreasing the number of pixels.

For example, in the case of the RGBG arrangement structure, more green (G) subpixels are disposed. G can visually react more sensitively than the other colors. Therefore, a visually clearer image quality can be sensed with an increase in the number of G subpixels.

In addition, two G can each serve to compensate for one of red (R) and blue (B). Two G subpixels can appropriately reinforce one of a signal of an R subpixel and a signal of a B subpixel so that colors of pixel parts are naturally expressed. Further, surrounding pixel information can be used to complement an insufficient part of a pixel part so that the resolution appears to be high.

In the display panel 1 of the present disclosure according to one embodiment, the transmission parts T can be disposed in the first active area AA1 more than the second active area AA2. Thus, the display panel 1 of the present disclosure according to one embodiment can apply the PenTile pixel structure to the first active area AA1 and the second active area AA2. In this way, the display panel 1 of the present disclosure according to one embodiment can increase the sharpness of the first active area AA1 and adjust the resolution of the first active area AA1 to be equivalent to the resolution of the second active area AA2.

However, the display panel 1 of the present disclosure is not limited thereto. For example, the first and second pixel parts P and Pn can further include a white light emission area or constitute another PenTile pixel structure to improve the luminous efficiency. Hereinafter, in the present disclosure, an example in which the first emission areas EA1 and EAn1 emit red light, the second emission areas EA2 and EAn2 emit green light, and the third emission areas EA3 and EAn3 emit blue light will be described.

The first emission area EA1 and the third emission area EA3 can be disposed side by side in the row direction X in the first pixel part P. The second emission area EA2 can be disposed at one side of the first emission area EA1 and the third emission area EA3 in the column direction Y. For example, the second emission area EA2 can be branched into a second-first emission area EA2-1 and a second-second emission area EA2-2.

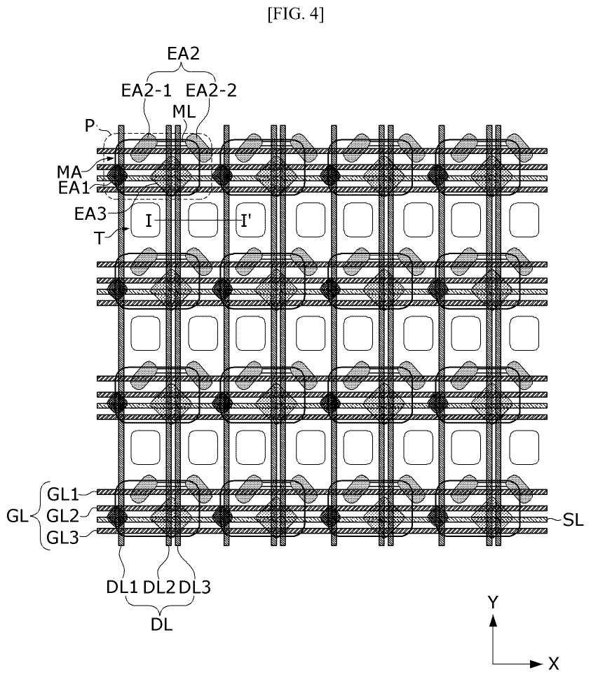

The second emission area EA2 included in the first pixel part P can include the second-first emission area EA2-1 and the second-second emission area EA2-2. The second-first emission area EA2-1 and the second-second emission area EA2-2 according to one embodiment can be disposed side by side in the row direction X at one side of the first emission area EA1 and the third emission area EA3 in the column direction Y. Accordingly, an area occupied by a component (ML of FIG. 4) connecting the second-first emission area EA2-1 and the second-second emission area EA2-2 can be relatively reduced. The reduced area of the connecting component can have an effect of improving a PSF for the first active area AA1.

The first-n emission area EAn1 and the third-n emission area EAn3 can be disposed side by side in the row direction X in the second pixel part Pn. The second-n emission area EAn2 can be branched into a second-first-n emission area EAn2-1 and a second-second-n emission area EAn2-2, and the second-first-n emission area EAn2-1 and the second-second-n emission area EAn2-2 can each be disposed at a point of intersection relative to one of the first-n and third-n emission areas EAn1 and EAn3 in the diagonal direction.

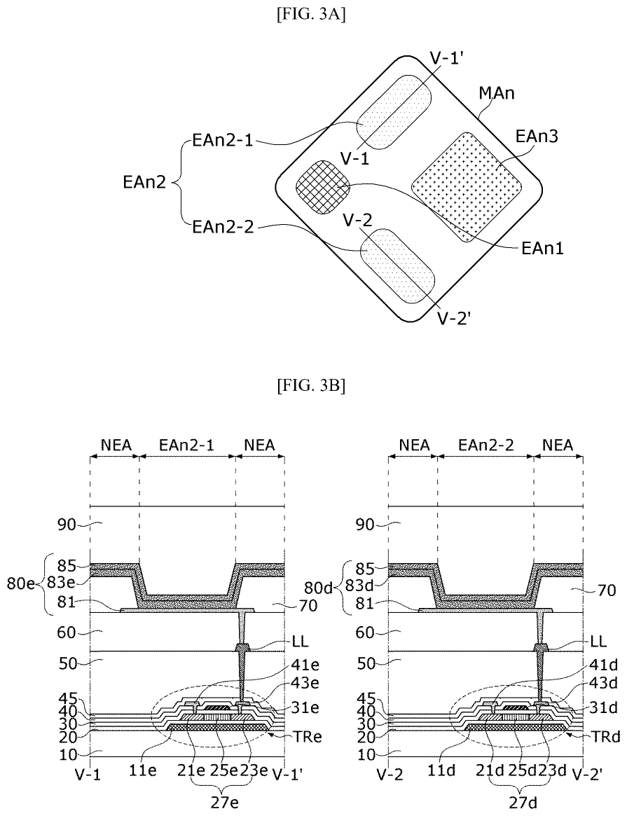

Referring to FIGS. 3A and 3B, the second-first-n emission area EAn2-1 and the second-second-n emission area EAn2-2 of the second pixel part Pn can be driven independently. Accordingly, in the second active area AA2, the sharpness and resolution of the screen can be increased while decreasing the number of pixels from the PenTile pixel structure.

Referring to FIG. 3A, the second active area AA2 can include a second driving circuit part MAn overlapping the second pixel part Pn. The second driving circuit part MAn can be an area in which circuits for driving luminous elements forming the emission areas EAn are disposed. The second driving circuit part MAn can apply a driving signal to luminous elements disposed in the second pixel part Pn. However, in the display panel 1 of the present disclosure, the area of the second driving circuit part MAn may not be limited to that illustrated. For example, the second driving circuit part MAn can include an area whose size is equal to or smaller than the area of the second pixel part Pn.

Referring to FIG. 3B, the second-first-n emission area EAn2-1 and the second-second-n emission area EAn2-2 of the second pixel part Pn can be areas that emit light by different transistors TRe and TRd. However, the transistors TRe and TRd of the present disclosure are not limited to those illustrated. In the present disclosure, for convenience of description, the transistors TRe and TRd each corresponding to one of the second-first-n emission area EAn2-1 and the second-second-n emission area EAn2-2 are illustrated.

The second-first-n emission area EAn2-1 and the second-second-n emission area EAn2-2 can be areas that correspond to different luminous elements 80e and 80d. The luminous elements 80e and 80d can include intermediate layers 83e and 83d each having a luminous layer.

The transistor TRe corresponding to the second-first-n emission area EAn2-1 can include an active layer 27e, a gate electrode 31e that overlaps a channel area 25e of the active layer 27e with a gate insulator 30 interposed therebetween, and a source electrode 41e and a drain electrode 43e connected to a source area 21e and a drain area 23e, respectively, at both sides of the active layer 27e.

The transistor TRd corresponding to the second-second-n emission area EAn2-2 can include an active layer 27d, a gate electrode 31d that overlaps a channel area 25d of the active layer 27d with a gate insulator 30 interposed therebetween, and a source electrode 41d and a drain electrode 43d connected to a source area 21d and a drain area 23d, respectively, at both sides of the active layer 27d.

The second driving circuit part MAn can include the two transistors TRe and TRd that correspond to the second-first-n emission area EAn2-1 and the second-second-n emission area EAn2-2, respectively. On the other hand, referring to FIG. 6B, a first driving circuit part MA can include one transistor TRb that corresponds to the second-first emission area EA2-1 and the second-second emission area EA2-2.

For example, the first driving circuit part MA can include fewer transistors than the second driving circuit part MAn. Accordingly, by relatively fewer transistors being included in the first active area AA1, the display panel 1 of the present disclosure can have an effect of improving a PSF.

The PSF can indicate an optical characteristic for diffracted light. Light can have properties of a particle and properties of a wave. Among these, due to light having the properties of a wave (for example, properties of spreading without moving straight), a direction of the light can change when the light encounters an obstacle or a gap. For example, diffraction can occur when light passes through an obstacle or a slit, and the light can be transformed into a specific pattern due to diffraction.

The specific pattern due to diffraction of light can be expressed using a Point Spread Function (PSF). The PSF can indicate the intensity of light for a specific pattern. The PSF can have a peak wavelength at -n-order, . . . , -second-order, -first-order, zeroth-order, first-order, second-order, . . . n-order points that are present to the left and right from the zero point (y-axis). The intensity can decrease away from the zeroth-order. Here, a zeroth-order value can be a component that moves straight along an original path without diffraction. A sensor embedded in the first active area AA1 can use a zeroth-order peak wavelength component with the highest light intensity.

Diffraction of light in a display panel can occur due to a patternized component, rather than a component formed on a top surface of a substrate, acting as an obstacle. For example, diffraction of light in a display panel can occur due to components such as patternized electrodes, lines, and spacers rather than components such as a planarization layer, an insulating layer, and a protective film formed on a top surface of a substrate. A diffraction pattern in a display panel can vary depending on thicknesses, intervals, and arrangement manners of metal lines or metal patterns. Further, even for insulating materials, diffraction of light in a display panel can occur depending on thicknesses, intervals, and arrangement manners thereof.

A small structure of several nanometers that is formed in a display panel has a size similar to a wavelength of light, and thus a diffraction phenomenon can be more prominent therein. For example, diffraction of light in a display panel can occur due to an opening or two adjacent lines having a slit-like shape. In addition, diffraction of light in a display panel can occur due to components such as spacers being disposed with a certain pattern on a plane.

Metal lines or metal patterns shown on a display panel can be arranged in an irregular manner as a whole. This is because light reaches sensor parts from outside the display panel after passing through metal lines and metal patterns disposed in various structures in different layers.

The irregularly arranged patterns can decrease the light intensity at the peak wavelength of the PSF. On the other hand, regularly arranged patterns can increase the light intensity at the peak wavelength of the PSF. This is because the regularly arranged patterns cause constructive interference between diffracted light waves.

In relation to the display panel 1 of the present disclosure, diffraction can occur as light entering the first active area AA1 passes through a transmission part T exposed by the second electrode 85 or passes between two adjacent lines (for example, between two data lines DL2 and DL3 adjacent to each other). Further, various patterned components disposed adjacent to each other on the substrate 10 can cause diffraction of light.

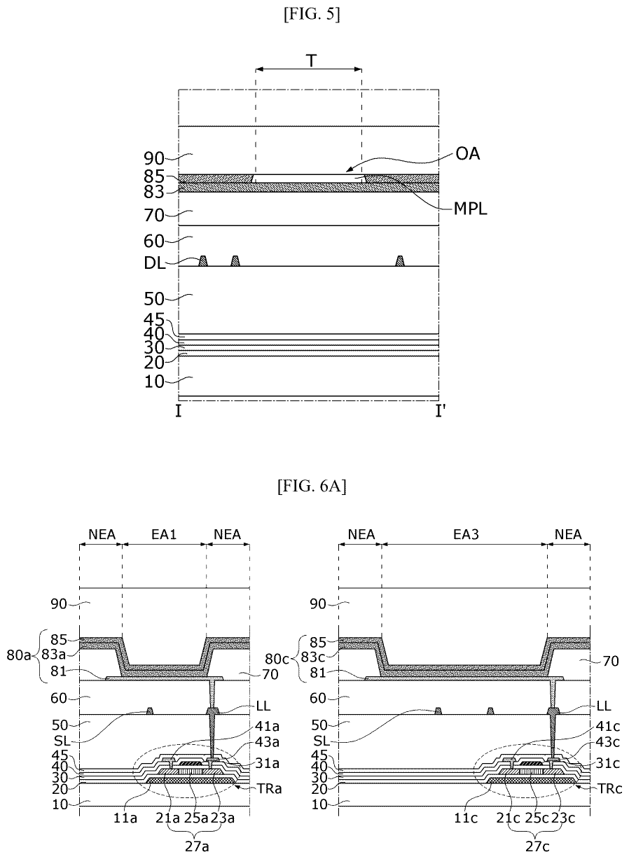

In the display panel 1 of the present disclosure according to one embodiment, lines such as signal lines GL, DL, and SL and various patterned electrode components (source, drain, and connection electrodes) can be disposed to overlap the second electrode 85. A pattern may not overlap an opening OA (see FIG. 5) of the second electrode 85. Accordingly, in the display panel 1 of the present disclosure according to one embodiment, since diffraction of light is minimized due to the absence of a patterned component that overlaps the transmission part T between the second electrode 85 and the substrate 10, a decrease in the light intensity at the peak wavelength of the PSF can be prevented. For example, the PSF can be improved.

In addition, in the display panel 1 of the present disclosure according to one embodiment, by the transmission parts T being arranged in a regular manner, the light intensity at the peak wavelength of the PSF can be increased. For example, the PSF can be improved. Accordingly, in the display panel 1 according to one embodiment of the present disclosure, image resolution of a sensor part disposed in the first active area AA1 can be improved.

The second-first emission area EA2-1 and the second-second emission area EA2-2 can be disposed in a row in the row direction X. In this way, since a space between the first pixel parts P adjacent to each other in the column direction Y is secured, the degree of freedom of design of the transmission parts T can relatively increase. In this way, in the display panel 1 of the present disclosure according to one embodiment, since the transmission parts T are easily arranged, there can be an effect of improving the PSF.

For example, as in FIG. 6B, the second-first emission area EA2-1 and the second-second emission area EA2-2 according to one embodiment can be driven simultaneously to minimize patterned components in the first active area AA1. In this way, one of the transistors for driving the second-first emission area EA2-1 and the second-second emission area EA2-2 can be removed.

Therefore, since the first active area AA1 of the present disclosure includes fewer transistors than the second active area AA2, the PSF can be improved.

Meanwhile, the third and third-n emission areas EA3 and EAn3 can have the largest area. The luminous efficiency of blue can be the lowest compared to red and green. For this reason, the third and third-n emission areas EA3 and EAn3 can be formed to have the largest area to improve the luminous efficiency.

The non-active area NA can include a pad part. Specifically, various lines and driving circuits can be disposed in the non-active area NA of the substrate 10, and a pad part to which an integrated circuit, a printed circuit, and the like are connected can be disposed.

Hereinafter, various embodiments relating to the first active area AA1 of the display panel 1 of the present disclosure will be described with reference to FIGS. 4 to 15F. The first active area AA1 according to one embodiment, which will be described below, does not necessarily correspond to the above-described structure of the second active area AA2. For example, the structure of the second active area AA2 can be an RGB pixel structure instead of the PenTile pixel structure.

FIG. 4 is a plan view of a display panel according to a first embodiments of the present disclosure. FIG. 5 is a cross-sectional view along line I-I′ of FIG. 4, and FIGS. 6A and 6B are cross-sectional views of emission areas of FIG. 4.

Referring to FIGS. 4 to 6B, a plurality of first pixel parts P can be disposed side by side in the row direction X. In addition, the plurality of first pixel parts P can be disposed apart from each other with a transmission part T disposed therebetween in the column direction Y. A separation distance between the plurality of first pixel parts P can be greater in the column direction Y than in the row direction X.

The first active area AA1 can include the plurality of first pixel parts P and a plurality of transmission parts T. In addition, various signal lines GL, DL, and SL for transmitting various signals to the plurality of first pixel parts P and various transistors for driving the first pixel parts P can be disposed in the first active area AA1.

Various signal lines extending from the non-active area NA can be disposed in the plurality of first pixel parts P. The transmission parts T can be more easily designed through an arrangement the plurality of first pixel parts P in consideration of the various signal lines. For example, in the display panel 1 of the present disclosure according to the first embodiment, by the plurality of first pixel parts P being disposed side by side in one direction, the degree of freedom of design of the transmission parts T can relatively increase.

In the display panel 1 according to the first embodiment, two transmission parts T can be disposed to correspond to one first pixel part P. In other words, two transmission parts T can be disposed between two first pixel parts P adjacent to each other in the column direction Y. Therefore, in the display panel 1 according to the first embodiment, the plurality of transmission parts T can be repeatedly disposed between an arbitrary first row and second row in which the plurality of first pixel parts P are disposed side by side.

In the transmission parts T according to the first embodiment, only an insulating layer can be disposed to improve transmittance. For example, the transmission parts T can be patterned areas of the second electrode 85. For example, in the transmission parts T, a buffer layer 20, a gate insulator 30, an interlayer insulator 40, a passivation layer 45, a first planarization layer 50, a second planarization layer 60, and a bank 70 can be disposed between the substrate 10 and an encapsulation layer 90.

Regular arrangement of the transmission parts T can be possible between data lines DL having a linear form and the first pixel parts P arranged side by side in the row direction X. The transmission parts T according to the first embodiment can be disposed in each space between the plurality of first pixel parts P and the data lines DL. The transmission parts T can be arranged in a regular manner in the row and column directions (X and Y) throughout the first active area AA. Accordingly, in the display panel 1 according to the first embodiment, since the light intensity at the zeroth-order peak wavelength of the PSF can be increased, the PSF can be improved. Further, in the display panel 1 according to the first embodiment, since more transmission parts T are disposed compared to other embodiments, the transmittance can be improved.

The transmission parts T may not overlap the data line DL. The transmission parts T can be spaced from each other with the data line DL disposed therebetween in the row direction X. Each data line DL can extend from the non-active area NA and be disposed in the first and second active areas AA1 and AA2 in the row direction X.

In the first active area AA1, a first data line DL1 can cross the first emission area EA1, and a second data line DL2 and a third data line DL3 can cross the third emission area EA3. Accordingly, the transmission parts T can be disposed between the first data line DL1 and the second data line DL2 adjacent to each other and between the third data line DL3 and the first data line DL1 adjacent to each other.

The data lines DL can be formed in a linear form between the transmission parts T compared to the plurality of first pixel parts P.

Conventionally, a display panel in which areas of transmission parts are increased to improve a recognition rate of sensors has been proposed. Conventionally, with an increase in the areas of the transmission parts, lines such as data lines passing between the transmission parts have been designed in a curved form, instead of a linear form, to go around the transmission parts. When lines of sensor parts are formed to be partially curved, a delay of a data signal or a gate signal can occur due to resistance gradually increasing toward a central portion.

However, in the display panel 1 of the present disclosure, the data lines DL between the transmission parts T can be formed in a linear form. Accordingly, the display panel 1 of the present disclosure can have an effect of lowering the resistance compared to curved lines while improving the PSF through the data lines DL having a linear form.

The transmission parts T can be spaced from each other with the gate line GL disposed therebetween in the column direction Y. Here, the gate lines GL can extend from the non-active area NA and be disposed in the first and second active areas AA1 and AA2 in the column direction Y.

In the first active area AA1, a first gate line GL1 can cross the second emission area EA2, a second gate line GL2 can cross the first and third emission areas EA1 and EA3, and a third gate line GL3 can cross the first and third emission areas EA1 and EA3. Accordingly, the transmission parts T can be disposed between the gate lines GL1, GL2, and GL3 that cross the two first pixel parts P adjacent to each other.

However, in the present disclosure, the data lines DL and the gate lines GL are not limited to those illustrated. For example, the data lines DL and the gate lines GL can have a partially bent area in at least the first pixel part P, a signal can be transmitted to two subpixels (emission areas) by one data line, and a signal can be transmitted to two subpixels (emission areas) by one gate line. However, in the present disclosure, the gate lines GL can overlap the plurality of first pixel parts P, and the data lines DL can have a form close to a linear form between the transmission parts T.

Signal lines SL can include various lines disposed in the first active area AA1. For example, the signal lines SL can include various types of voltage supply lines for driving the plurality of first pixel parts P or lines connected to a camera and a sensor.

The signal lines SL can extend from the non-active area NA and be disposed to cross the first pixel part P of the first active area AA1 or cross between neighboring first pixel parts P. Although the signal lines SL are illustrated in the drawings as being formed in the row direction X, the display panel of the present disclosure is not limited thereto. For example, the signal lines SL can be formed in the column direction Y, or one or more signal lines SL can be formed in each of the row direction X and the column direction Y.

The first driving circuit part MA can include circuit components disposed in the first pixel parts P while excluding the gate lines GL, the data lines DL, and the signal lines SL in the form of lines that extend from the non-active area NA. For example, the first driving circuit part MA can include driving elements, connection electrodes, or the like as circuits for driving luminous elements 80a, 80b, and 80c. The first driving circuit part MA can include one or more transistors as driving elements for each luminous element. For example, the driving elements can include a driving transistor, a scan transistor for transmitting a data voltage to the driving transistor, a storage capacitor for maintaining a certain voltage during one frame, etc.

The first driving circuit part MA can overlap the first pixel part P. The first driving circuit part MA can occupy a larger area than the first pixel part P but may not overlap the transmission part T.

In the first active area AA1, the plurality of first pixel parts P can include emission areas EA1, EA2, and EA3 that emit light of different colors. The first emission area EA1 can emit red light, the second emission area EA2 can emit green light, and the third emission area EA3 can emit blue light. However, the display panel of the present disclosure is not limited thereto.

The second emission area EA2 can include the second-first emission area EA2-1 and the second-second emission area EA2-2. The second-first emission area EA2-1 and the second-second emission area EA2-2 according to the first embodiment can be disposed side by side in the row direction X.

The second-first emission area EA2-1 and the second-second emission area EA2-2 according to the first embodiment can be driven simultaneously to minimize patterned components disposed in the first driving circuit part MA. Accordingly, in the present disclosure, by removing one of the transistors for driving the second-first emission area EA2-1 and the second-second emission area EA2-2, there can be an effect of improving the PSF.

A connection pattern ML can be a component connecting the second-first emission area EA2-1 and the second-second emission area EA2-2. For example, the connection pattern ML can be a component of a first electrode that constitutes the second-first and second-second luminous elements. For example, the second-first and second-second emission areas EA2-1 and EA2-2 can have structures that share the first electrode.

The second-first emission area EA2-1 and the second-second emission area EA2-2 according to the first embodiment can be disposed side by side in the row direction X at one side of the first emission area EA1 and the third emission area EA3 in the column direction Y. Accordingly, an area occupied by the connection pattern ML connecting the second-first emission area EA2-1 and the second-second emission area EA2-2 can be relatively reduced. The reduced area of the connection pattern ML can have an effect of improving the PSF for the first active area AA1.

Meanwhile, the third emission area EA3 can have the largest area. The luminous efficiency of blue can be the lowest compared to red and green. For this reason, the third emission area EA3 can be formed to have the largest area to improve the luminous efficiency.

Referring to FIGS. 6A and 6B, the first emission area EA1 and the third emission area EA3 can include one driving transistor TRa and one driving transistor TRc, respectively, for one emission area. On the other hand, the second emission area EA2 can include one driving transistor TRb for two emission areas EA2-1 and EA2-2. The transistors TRa, TRb, and TRc of the first to third emission areas EA1, EA2, and EA3 are schematically illustrated in the drawings, and the structures of the transistors of the present disclosure are not limited thereto.

The transistors TRa, TRb, and TRc can include active layers 27a, 27b, and 27c, gate electrodes 31a, 31b, and 31c that overlap channel areas 25a, 25b, and 25c of the active layers 27a, 27b, and 27c with gate insulators 30 interposed therebetween, and source electrodes 41a, 41b, and 41c and drain electrodes 43a, 43b, and 43c connected to source areas 21a, 21b, and 21c and drain areas 23a, 23b, and 23c, respectively, at both sides of the active layers 27a, 27b, and 27c.

The active layers 27a, 27b, and 27c of the transistors TRa, TRb, and TRc can have the source areas 21a, 21b, and 21c and the drain areas 23a, 23b, and 23c at both sides with the channel areas 25a, 25b, and 25c disposed therebetween. The source areas 21a, 21b, and 21c and the drain areas 23a, 23b, and 23c can each be formed of a semiconductor material into which n-type or p-type impurities are injected. The channel areas 25a, 25b, and 25c overlapping the gate electrodes 31a, 31b, and 31c can be formed of a semiconductor material into which the n-type or p-type impurities are not injected.

The gate electrodes 31a, 31b, and 31c of the transistors TRa, TRb, and TRc can overlap the channel areas 25a, 25b, and 25c of the active layers 27a, 27b, and 27c with the gate insulator 30 disposed therebetween while having the same width as the channel areas 25a, 25b, and 25c. For example, the gate electrodes 31a, 31b, and 31c can be a single layer or multiple layers made of any one of molybdenum (Mo), aluminum (Al), chromium (Cr), gold (Au), titanium (Ti), nickel (Ni), neodymium (Nd), and copper (Cu) or an alloy thereof.

Meanwhile, light blocking layers 11a, 11b, and 11c on the substrate 10 can overlap at least the channel areas 25a, 25b, and 25c of the active layers 27a, 27b, and 27c and can be disposed at lower sides of the active layers 27a, 27b, and 27c. The light blocking layers 11a, 11b, and 11c can prevent external light from permeating into the substrate 10 and being transmitted to the transistors TRa, TRb, and TRc.

For example, the light blocking layers 11a, 11b, and 11c can be made of a single layer of a metal material such as molybdenum (Mo), titanium (Ti), aluminum-neodymium (Al—Nd), aluminum (Al), or chromium (Cr) or an alloy thereof or can be made of a multi-layer structure using the same.

The buffer layer 20 on the light blocking layers 11a, 11b, and 11c can cover the light blocking layers 11a, 11b, and 11c. For example, the buffer layer 20 can be made of a single-layer or multi-layer structure made of silicon oxide (SiOx) or silicon nitride (SiNx).

The interlayer insulator 40 on the buffer layer 20 can include a contact hole that exposes each of the source areas 21a, 21b, and 21c and the drain areas 23a, 23b, and 23c of the active layers 27a, 27b, and 27c and can cover the gate electrodes 31a, 31b, and 31c. For example, the interlayer insulator 40 can be made of an inorganic insulating material. For example, the interlayer insulator 40 can be made of a single layer or multiple layers of a silicon oxide film (SiOx), a silicon nitride film (SiNx), or a silicon oxynitride film (SiOxNy).

The source electrodes 41a, 41b, and 41c and the drain electrodes 43a, 43b, and 43c can be disposed in the same layer on the interlayer insulator 40. The source electrodes 41a, 41b, and 41c and the drain electrodes 43a, 43b, and 43c are connected to the source areas 21a, 21b, and 21c and the drain areas 23a, 23b, and 23c, respectively, of the active layers 27a, 27b, and 27c through a contact hole.

For example, the source electrodes 41a, 41b, and 41c and the drain electrodes 43a, 43b, and 43c can be made of a single layer of a metal material such as molybdenum (Mo), aluminum (Al), chromium (Cr), gold (Au), titanium (Ti), nickel (Ni), neodymium (Nd), or copper (Cu) or an alloy thereof or can be made of a multi-layer structure using the same.

The passivation layer 45 on the interlayer insulator 40 can cover the transistors TRa, TRb, and TRc. By this, the transistors TRa, TRb, and TRc can be protected by the passivation layer 45. For example, the passivation layer 45 is a type of inorganic insulator and can be made of a single layer or multiple layers of a silicon oxide film (SiOx), a silicon nitride film (SiNx), or a silicon oxynitride film (SiOxNy).

At least the first and second planarization layers 50 and 60 can be disposed on the passivation layer 45.

The first planarization layer 50 can be formed with a thickness that allows a surface step on upper portions of the transistors TRa, TRb, and TRc to be sufficiently planarized and can be formed of an organic insulator. However, the present disclosure is not limited thereto. For example, the passivation layer 45 can be omitted when the first planarization layer 50 also serves to protect the transistors TRa, TRb, and TRc.

For example, the first planarization layer 50 is a type of organic insulator and can be any one of photo acryl, polyimide, benzocyclobutene resin, and acrylate, and in some cases, the first planarization layer 50 can be formed of multiple layers.

A connection electrode LL can be disposed on the first planarization layer 50. The connection electrode LL can be formed together with signal lines SL of the first planarization layer 50. The connection electrode LL can electrically connect the first electrode 81 of the luminous elements 80a, 80b, and 80c and the transistors TRa, TRb, and TRc through a contact hole.

For example, the connection electrode LL can be made of a single layer of a metal material such as molybdenum (Mo), aluminum (Al), chromium (Cr), gold (Au), titanium (Ti), nickel (Ni), neodymium (Nd), or copper (Cu) or an alloy thereof or can be made of a multi-layer structure using the same.

The second planarization layer 60 can be disposed on the first planarization layer 50. The second planarization layer 60 can cover various circuits or signal lines SL and the connection electrode LL disposed on the first planarization layer 50. The second planarization layer 60 is a type of organic insulator and can be any one of photo acryl, polyimide, benzocyclobutene resin, and acrylate.

The luminous elements 80a, 80b, and 80c can be disposed on the second planarization layer 60. The luminous elements 80a, 80b, and 80c can be driven by an electric field formed between the first electrode 81 and the second electrode 85 and light can be emitted from intermediate layers 83a, 83b, and 83c when a current supplied from the power voltage line flows in the second electrode 85 and a high-voltage current is supplied from the transistors TRa, TRb, and TRc to the first electrode 81.

The emission areas EA1, EA2, and EA3 can be areas in which light is emitted from the luminous elements 80a, 80b, and 80c. For example, the emission areas EA1, EA2, and EA3 can be areas exposed from the bank 70. However, the display panel of the present disclosure is not limited thereto, and the emission areas can also include a side surface and an upper surface of the bank 70 where the intermediate layers 83a, 83b, and 83c can be disposed.

The first electrode 81 can be disposed in each subpixel and can be electrically connected to each of the transistors TRa, TRb, and TRc. When the display panel of the present disclosure is a top emission type, the first electrode 81 can be formed to have higher reflection efficiency than the second electrode 85 to reflect light generated from the intermediate layers 83a, 83b, and 83c.

For example, the first electrode 81 can be formed of a multi-layer structure including a transparent conductive layer and an opaque conductive layer having high reflection efficiency. The transparent conductive layer of the first electrode 81 can be made of a material with a relatively large work function value such as indium tin oxide (ITO) or indium zinc oxide (IZO), and the opaque conductive layer can be formed of a single layer or multiple layers made of any one selected from the group consisting of silver (Ag), aluminum (Al), copper (Cu), molybdenum (Mo), titanium (Ti), nickel (Ni), chromium (Cr), or tungsten (W) or an alloy thereof.

For example, the first electrode 81 can be formed of a structure in which a transparent conductive layer, an opaque conductive layer, and a transparent conductive layer are sequentially laminated or can be formed of a structure in which a transparent conductive layer and an opaque conductive layer are sequentially laminated.

The intermediate layers 83a, 83b, and 83c on the first electrode 81 can be disposed across the entire first and second active areas AA1 and AA2. Specifically, the intermediate layers 83a, 83b, and 83c can be disposed on the first electrode 81 that is open due to the bank 70 and the side surface and upper surface of the bank 70.

The intermediate layers 83a, 83b, and 83c can also be organic layers of a single stack that is made of multiple layers including a hole injection layer HIL, a hole transport layer HTL, an emission layer EML, an electron transport layer ETL, and an electron injection layer EIL. In some cases, the intermediate layers 83a, 83b, and 83c can have a tandem structure including a plurality of stacks (a first stack and a second stack) each having an emission layer and a charge generation layer (CGL) disposed between the stacks. In addition, the tandem structure of the intermediate layers 83a, 83b, and 83c is not limited to the 2-stack structure and can be made of a plurality of stacks, for example, 3 stacks or more.

In the plurality of stacks, each emission layer can be an emission layer of the same color that emits any one of red light, green light, and blue light and can be disposed to overlap each of the emission areas EA1, EA2, and EA3. The plurality of layers of the intermediate layers 83a, 83b, and 83c excluding the emission layers can be provided as a common mask on top of the substrate 10. Alternatively, when white light is emitted through emission layers in a multi-stack structure of 2 stacks or more or 3 stacks or more, each of the emission layers can be provided as a common mask on top of the substrate 10 like other intermediate layers 83a, 83b, and 83c. Meanwhile, the charge generation layer can be made of a double layer of an n-type layer and a p-type layer. The n-type charge generation layer and the p-type charge generation layer of the charge generation layer can include an n-type dopant and a p-type dopant, respectively.

The second electrode 85 can be disposed in the active areas AA1 and AA2 while facing the first electrode 81 on the intermediate layers 83a, 83b, and 83c. In some cases, the second electrode 85 can also be disposed in the non-active area NA to come into contact with a circuit part of the non-active area NA.

The second electrode 85 can include an opening OA. The opening OA can completely overlap the transmission part T of the substrate 10. The opening OA may not overlap patterned components such as the first driving circuit part MA, the data line DL, the gate line GL, and the signal line SL.

Light entering from outside the display panel 1 can move from a place where refractivity is low to a place where refractivity is high based on the second electrode 85. For example, light can move from the encapsulation layer 90 to the second electrode 85. A majority of light can be reflected when it moves to the second electrode 85 where refractivity is relatively high. Only a portion of the light that is transmitted through the second electrode 85 can be diffracted due to the components of the first driving circuit part MA.

In this way, in the display panel 1 of the present disclosure according to one embodiment, diffraction can be minimized by the first driving circuit part MA overlapping the second electrode 85 instead of being disposed on the transmission part T. Therefore, in the display panel 1 of the present disclosure, the PSF can be improved by preventing a decrease in the light intensity at the peak wavelength of the PSF.

When the display panel of the present disclosure is a top emission type, the second electrode 85 can be made of a conductive layer made of a transparent material. For example, the second electrode 85 can be made of a transparent conductive material such as indium tin oxide (ITO) or indium zinc oxide (IZO).

A metal patterning layer MPL can be disposed in the same layer as the second electrode 85 on the intermediate layer 83. The metal patterning layer MPL can be disposed to form the opening OA of the second electrode 85. Thus, the metal patterning layer MPL can include the transmission part T therein. However, the present disclosure is not limited to configuring the metal patterning layer MPL as a component for patterning the second electrode 85. For example, the second electrode 85 can be patterned through a masking process without the metal patterning layer MPL. In the following embodiments, an example in which the metal patterning layer MPL is included in the opening OA of the second electrode 85 will be described.

The metal patterning layer MPL can have low affinity to a conductive material and thus can have a surface on which deposition of the second electrode 85 made of a conductive material is suppressed. To this end, the metal patterning layer MPL can include a material having the following characteristics.

The metal patterning layer MPL can include a polycyclic aromatic compound including organic molecules including one or more of heteroatoms such as nitrogen (N), sulfur(S), oxygen (O), phosphorus (P), and aluminum (Al) as an organic material and an organic material including an organic polymer. The polycyclic aromatic compound can include an organic molecule including a core moiety and at least one terminal moiety bonded to the core moiety.

For example, the material of the metal patterning layer MPL can include 3-(4-biphenyl)-4-phenyl-5-tert-butylphenyl-1,2,4-triazole (TAZ), aluminum (III) bis(2-methyl-8-quinolinato)-4-phenylphenolate (BA1q), 2-(4-(9,10-di(naphthalene-2-yl) anthracene-2-yl)phenyl)-1-phenyl-1H-benzo-[D]imidazole, 8-hydroxyquinoline lithium (Liq), N(diphenyl-4-yl) 9,9-dimethyl-N-(4 (9-phenyl-9H-carbazole-3-yl)phenyl)-9H-fluorene-2-amine, etc.

When deposited on a surface of the metal patterning layer MPL, the material of the second electrode 85 may not stick to the surface of the metal patterning layer MPL due to having low affinity to the metal patterning layer MPL. In other words, the second electrode 85 can have a very low probability of sticking to the surface of the metal patterning layer MPL.

Here, the probability of sticking to the surface can be measured by depositing an amount of conductive material necessary to form a closed-pack layer having an average thickness of 1 nm on a surface of the metal patterning layer MPL. Specifically, the probability of the conductive material sticking to the surface of the metal patterning layer MPL can be derived by simultaneously depositing conductive materials on the surface of the metal patterning layer MPL and the substrate and when an average thickness of a closed-pack layer on the surface of the metal patterning layer MPL reaches 1 nm, comparing it with an average thickness of the conductive material deposited on the substrate.

The material of the second electrode 85 can stick to the surface of the metal patterning layer MPL through nucleus generation and growth processes. However, as described above, the second electrode 85 made of a conductive material can have a low probability of sticking to the metal patterning layer MPL. The probability of the conductive material sticking to the surface of the metal patterning layer MPL can be 0.3 (or 30%) at most and 0.0008 (or 0.08%) at the least.

Accordingly, in the nucleus generation and growth processes, conductive materials constituting the second electrode 85 can be detached due to low affinity to the metal patterning layer MPL. As a result, the second electrode 85 may not be formed on the metal patterning layer MPL.

Since the metal patterning layer MPL is made of an organic material, a transmittance of the transmission part T may not decrease due to the metal patterning layer MPL. Therefore, in the display panel of the present disclosure, the second electrode 85 can be patterned through the metal patterning layer MPL without a decrease in the transmittance of the transmission part T.

Meanwhile, the bank 70 can cover an edge of the first electrode 81 and can be disposed on the second planarization layer 60. The bank 70 is an area for defining the emission area EA and can include an opening that exposes the first electrode 81. For example, the bank 70 can be made of an organic material such as a polyimide, acrylate, or benzocyclobutene series resin.

The encapsulation layer 90 can be disposed on the bank 70. The encapsulation layer 90 can be formed of a plurality of layers. For example, the encapsulation layer 90 can be made of a structure in which an inorganic layer and an organic layer are alternately laminated. The inorganic layer can be made of a metal oxide, a metal nitride, a metal carbide, or a compound thereof. For example, the inorganic layer can include an inorganic material such as AlOx, TiO₂, ZrO, SiOx, AlON, AlN, SiNx, SiOxNy, InOx, or YbOx. The organic layer can include a polymer-based material. The polymer-based material can include acryl resin, epoxy resin, silicone resin, polyimide, or polyethylene.

In the following embodiments, description of components identical to those of the first embodiment will be omitted or may be briefly provided.

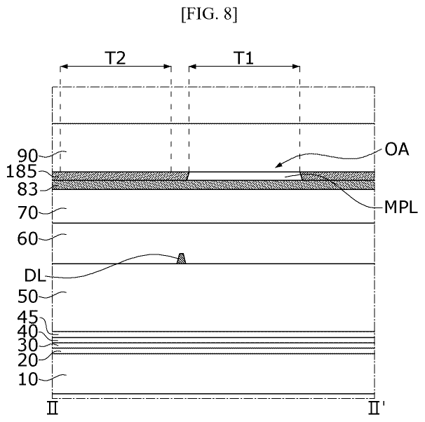

FIGS. 7A to 7D are plan views of display panels according to second to fifth embodiments of the present disclosure. FIG. 8 is a cross-sectional view along line II-II′ of FIG. 7A.

The display panels according to the second to fifth embodiments of the present disclosure can include a first transmission part T1 and a second transmission part T2.

The first transmission part T1 and the second transmission part T2 can have different transmittances. The transmittance of the first transmission part T1 can be higher than the transmittance of the second transmission part T2. Referring to FIG. 8, the first transmission part T1 can be a patterned opening OA of a second electrode 185, and the second transmission part T2 can be an arbitrary area that is an area between a first pixel part P and a data line DL and in which the second electrode 185 is not patterned. Therefore, the second transmission part T2 can have an area that is larger than or equal to an area of the first transmission part T1. In addition, a metal patterning layer can be disposed on the first transmission part T1, and the second transmission part T2 can further include the second electrode 185 compared to the first transmission part T1.

A first active area AA1 can include a first pattern including a plurality of first transmission parts T1, and in the first pattern, at least one data line DL can be disposed on at least one boundary portion among boundary portions between the first transmission parts T1. In addition, the first pattern and the second transmission part T2 can be alternately disposed in the row direction X.

An embodiment in which three or two first transmission parts T1 are included for the first pattern is shown in FIGS. 7A and 7B. However, the display panel of the present disclosure is not limited thereto. For example, the first pattern can include four or more first transmission parts T1.

In addition, in the second to fifth embodiments, the number of first transmission parts T1 is shows as being larger than or equal to the number of second transmission parts T2. However, the display panel of the present disclosure is not limited thereto. For example, the number of first transmission parts T1 can be smaller than the number of second transmission parts T2.

Referring to FIG. 7A, when three first transmission parts T1 are disposed in an arbitrary first row, one second transmission part T2 can be disposed for every three first transmission parts T1. The first transmission parts T1 and the second transmission parts T2 can be arranged with the same rule as in the first row in an arbitrary second row adjacent to the first row, and among the three first transmission parts T1 disposed adjacent to one another in the first row, the first transmission part T1 at the center can be disposed in the same column as the second transmission part T2 in the second row.

Referring to FIG. 7B, when two first transmission parts T1 are disposed in an arbitrary first row, one second transmission part T2 can be disposed for every two first transmission parts T1. The first transmission parts T1 and the second transmission parts T2 can be arranged with the same rule as in the first row in an arbitrary second row adjacent to the first row, and among the two first transmission parts T1 disposed adjacent to one another in the first row, one first transmission part T1 can be disposed in the same column as the second transmission part T2 in the second row.

Referring to FIG. 7C, first transmission parts T1 and second transmission parts T2 can be alternately disposed in an arbitrary first row. The first transmission parts T1 and the second transmission parts T2 can be arranged with the same rule as in the first row in an arbitrary second row adjacent to the first row, and the first and second transmission parts T1 and T2 of the first row can be disposed in the same column as the first and second transmission parts T1 and T2 of the second row.

Referring to FIG. 7D, first transmission parts T1 and second transmission parts T2 can be alternately disposed in an arbitrary first row. The first transmission parts T1 and the second transmission parts T2 can be arranged with the same rule as in the first row in an arbitrary second row adjacent to the first row, the first transmission part T1 of the first row can be disposed in the same column as the second transmission part T2 of the second row, and the second transmission part T2 of the first row can be disposed in the same column as the first transmission part T1 of the second row.

By including the first and second transmission parts T1 and T2 having different transmittances, the display panels of the present disclosure according to the second to fifth embodiments can improve the PSF while improving the transmittance of the first active area AA1. By including the first transmission parts T1, the display panel of the present disclosure can improve the transmittance of the first active area AA1. In addition, by including the second transmission parts T2, the display panel of the present disclosure can reduce diffraction of light caused by the opening OA of the second electrode 85 and thus can improve the PSF.

In addition, in the second to fifth embodiments, by arranging the first transmission parts T1 and the second transmission parts T2 in a regular manner, the light intensity at the peak wavelength of the PSF can be increased. For example, the PSF can be improved. Accordingly, in the display panel of the present disclosure, image resolution of a sensor part disposed in the first active area AA1 can be improved.

In addition, although an example in which the first transmission portion T1 does not overlap with the second electrode 85 is described above, the configuration of the first transmission portion T1 is not limited thereto. For example, the first transmission portion T1 can be configured in another manner according to actual needs so that the transmittance of the first transmission portion T1 is higher than the transmittance of the second transmission portion T1, thereby improving the transmittance of the first active area AA1.

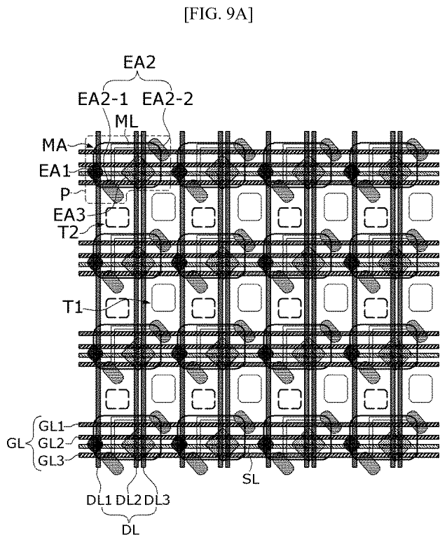

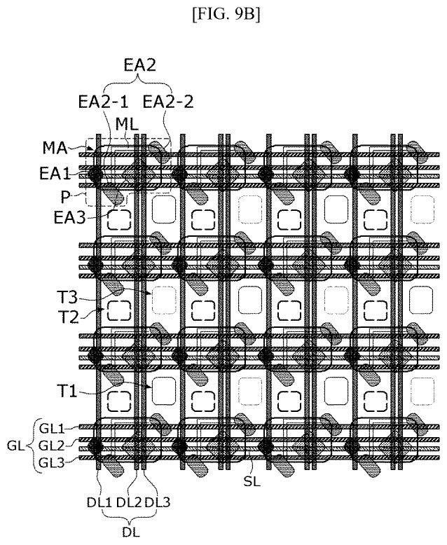

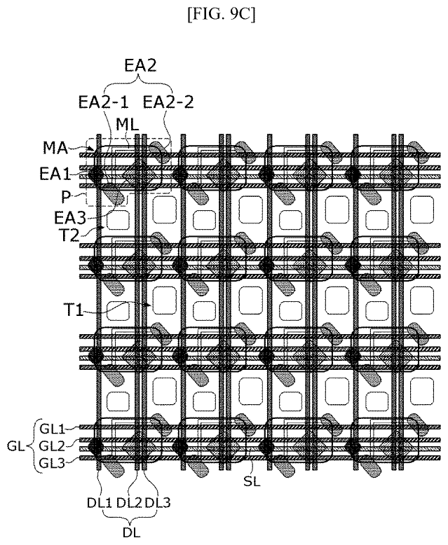

FIGS. 9A to 9C are plan views of display panels according to sixth to eighth embodiments of the present disclosure.

Referring to FIGS. 9A to 9C, in the display panels of the present disclosure according to the sixth to eighth embodiments, the arrangement of emission areas EA of first pixel parts P can be different compared to the first embodiment. In addition, the display panels of the present disclosure according to the sixth to eighth embodiments can further include second transmission parts T2 compared to the first embodiment due to changes in the arrangement structure of the emission areas EA.

The emission areas EA can include first to third emission areas EA1, EA2, and EA3. The second emission area EA2 can be branched into and include a second-first emission area EA2-1 and a second-second emission area EA2-2.

The first and third emission areas EA1 and EA3 can be disposed side by side in the row direction X. The second-first and second-second emission areas EA2-1 and EA2-2 can each be disposed in a diagonal direction of the third emission area EA3.

A connection pattern ML can be a component connecting the second-first emission area EA2-1 and the second-second emission area EA2-2. For example, the connection pattern ML can be a component of the first electrode 81 (see FIG. 6B) constituting the second luminous element 80b (see FIG. 6B).

The connection pattern ML according to the sixth to eighth embodiments can be disposed between the first emission area EA1 and the third emission area EA3. In this way, the connection pattern ML can connect the second-first and second-second emission areas EA2-1 and EA2-2 disposed in a diagonal direction of the third emission area EA3.

Referring to FIG. 9A, a first transmission part T1 and a second transmission part T2 can be disposed between two first pixel parts P adjacent in the column direction Y. The first transmission part T1 and the second transmission part T2 can have different transmittances and can be formed to have different areas. The second transmission part T2 is an arbitrary area and can include a larger area than illustrated. Therefore, the area of the second transmission part T2 is not limited to that illustrated and can be substantially larger than an area of the first transmission part T1.

The first transmission part T1 and the second transmission part T2 can have different transmittances. The transmittance of the first transmission part T1 can be higher than the transmittance of the second transmission part T2. The first transmission part T1 can be a patterned area of a second electrode, and the second transmission part T2 can be an arbitrary area that is formed from the first pixel parts P and the data lines DL. The second transmission part T2 can be an area in which patterned components are not disposed and the second electrode is not patterned.

In the first transmission part T1, only an insulating layer can be disposed to improve transmittance. In addition, the first transmission part T1 may not overlap a patterned component in order to improve the PSF. For example, the first driving circuit part MA, the data line DL, the gate line GL, the signal line SL, and the like may not be disposed on the first transmission part T1. Since the second electrode is not patterned in order to improve the PSF, the second transmission part T2 can include the second electrode.

At the first pixel parts P, the second-first emission area EA2-1 can be disposed to protrude between two first pixel parts P adjacent in the column direction Y. Accordingly, separation spaces of different areas can be formed at both sides of the data lines DL2 and DL3 between the two first pixel parts P adjacent in the column direction Y.

Between the two first pixel parts P adjacent in the column direction Y, a first transmission part T1 with a high transmittance can be disposed in a separation space with a relatively wide area, and a second transmission part T2 with a low transmittance can be disposed in a separation space with a relatively narrow area.

The first transmission parts T1 and the second transmission parts T2 can be alternately disposed in the row direction X. In addition, the first transmission parts T1 and the second transmission parts T2 can each be repeatedly disposed in the column direction Y.

Accordingly, in the display panel of the present disclosure, since the second transmission parts T2 are included, diffraction of light caused by the opening OA of the second electrode 85 can occur less compared to the embodiment in which the second transmission parts T2 are not included. In addition, by the first transmission parts T1 and the second transmission parts T2 being arranged in a regular manner, the light intensity at the peak wavelength of the PSF can be increased. For example, the PSF can be improved. Accordingly, in the display panel of the present disclosure, image resolution of a sensor part disposed in the first active area AA1 can be improved.

Referring to FIG. 9B, the display panel according to the seventh embodiment can include first to third transmission parts T1, T2, and T3 that have different features.

The first transmission part T1 can have a different transmittance from the second and third transmission parts T2 and T3. The transmittance of the first transmission part T1 can be higher than the transmittance of the second and third transmission parts T2 and T3. The first transmission part T1 can be a patterned area of a second electrode. The second and third transmission parts T2 and T3 can further include the second electrode compared to the first transmission part T1.

The second and third transmission parts T2 and T3 can be formed to have different areas and can have the same transmittance. The second and third transmission parts T2 and T3 are arbitrary areas and thus sizes thereof are not particularly limited, but at least the third transmission part T3 can be formed to have a larger area than the second transmission part T2. The third transmission part T3 can include a larger area than the second transmission part T2 because the third transmission part T3 is not affected by a protruding pixel (for example, EA2-1 of FIG. 9B).

The first transmission part T1 and the second transmission part T2 can be disposed between the two first pixel parts P adjacent in an arbitrary first column, and the second transmission part T2 and the third transmission part T3 can be disposed between the two first pixel parts P adjacent in a second column adjacent to the first column. In addition, the first transmission part T1 and the third transmission part T3 can be disposed to intersect each other in another adjacent row. By further including the third transmission part T3 compared to the sixth embodiment, the display panel according to the seventh embodiment can further improve the PSF by reducing diffraction of light.

Referring to FIG. 9C, the display panel according to the eighth embodiment can include first and second transmission parts T1 and T2 having different areas. The first transmission part T1 can have a larger area than the second transmission part T2. The first transmission part T1 can include a larger area than the second transmission part T2 because the first transmission part T1 is not affected by a protruding pixel (for example, EA2-1 of FIG. 9C). The first and second transmission parts T1 and T2 can be alternately disposed in the row direction.

The first and second transmission parts T1 and T2 can be patterned areas of the second electrode. For example, the first and second transmission parts T1 and T2 can be areas in which a metal patterning layer is disposed. In this way, the first and second transmission parts T1 and T2 can have the same transmittance.

In the display panel according to the eighth embodiment, since an open ratio of the second electrode is higher compared to the sixth and seventh embodiments, the open ratio can be relatively improved. In addition, the PSF can be improved by patterned components not being disposed on the transmission parts T1 and T2. [Table 1] below shows measurements of zeroth order ratio (ZOR) values of the PSF and open ratios of transmission parts for comparison groups A1 to A5.

The ZOR value of the PSF indicates a ratio of a zeroth-order diffraction component in the PSF. The open ratio of the transmission part indicates a ratio of an area occupied by the transmission part to an area occupied by the second electrode in the first active area.

TABLE 1

| | Zeroth order ratio (ZOR) | Open ratio (OR) of |
|---|---|---|
| | (%) | transmission part (%) |
| A1 | 37 | 22 |
| A2 | 47 | 6 |
| A3 | 50 | 6 |
| A4 | 48 | 6 |
| A5 | 52 | 8 |

In the above, A1 is a conventional display panel and is an embodiment in which an open ratio of transmission parts is 22%, and patterns such as lines and spacers are disposed on the transmission parts.

A2 is a display panel according to one embodiment of the present disclosure and is an embodiment in which an open ratio of transmission parts is 6%, patterned components are not disposed on the transmission parts T, the second-first and second-second emission areas EA2-1 and EA2-2 are arranged in the diagonal direction of the third emission area EA3, and the second-first and second-second emission areas EA2-1 and EA2-2 are driven independently.

A3 is a display panel according to one embodiment of the present disclosure and is an embodiment in which an open ratio of transmission parts is 6%, patterned components are not disposed on the transmission parts T, the second-first and second-second emission areas EA2-1 and EA2-2 are arranged in the diagonal direction of the third emission area EA3, and the second-first and second-second emission areas EA2-1 and EA2-2 are driven using a single transistor.

A4 is a display panel according to one embodiment of the present disclosure and is an embodiment in which an open ratio of transmission parts is 6%, patterned components are not disposed on the transmission parts T, the second-first and second-second emission areas EA2-1 and EA2-2 are disposed side by side, and the second-first and second-second emission areas EA2-1 and EA2-2 are driven independently.

A5 is a display panel according to one embodiment of the present disclosure and is an embodiment in which an open ratio of transmission parts is 8%, patterned components are not disposed on the transmission parts T, the second-first and second-second emission areas EA2-1 and EA2-2 are disposed side by side, and the second-first and second-second emission areas EA2-1 and EA2-2 are driven using a single transistor.

Referring to [Table 1], in the display panels of the present disclosure, the ZOR can be increased by decreasing the open ratio of the transmission parts and not placing patterned components on the transmission parts.

Comparing A2 and A3 of [Table 1], in the display panels of the present disclosure, the ZOR can be improved by placing one less transistor in an area overlapping the second electrode. This can indicate that diffraction of light due to transistors can be reduced and the PSF is improved.

Comparing A2 and A4 of [Table 1], in the display panels of the present disclosure, the ZOR can be improved by placing the second-first and second-second emission areas adjacent to each other in an area overlapping the second electrode without decreasing the number of transistors. This can indicate that diffraction of light due to a decrease in an area of a component connecting the second-first and second-second emission areas can be reduced and the PSF is improved.

Comparing A4 and A5 of [Table 1], in the display panels of the present disclosure, the ZOR can be improved by placing the second-first and second-second emission areas side by side and decreasing the number of transistors by one despite an increase in the open ratio of the transmission parts. This can indicate that PSF can be improved by not placing patterned components on the transmission parts, placing patterned components in areas not overlapping the transmission parts, or decreasing areas of patterned components rather than by increasing the open ratio of the transmission parts.

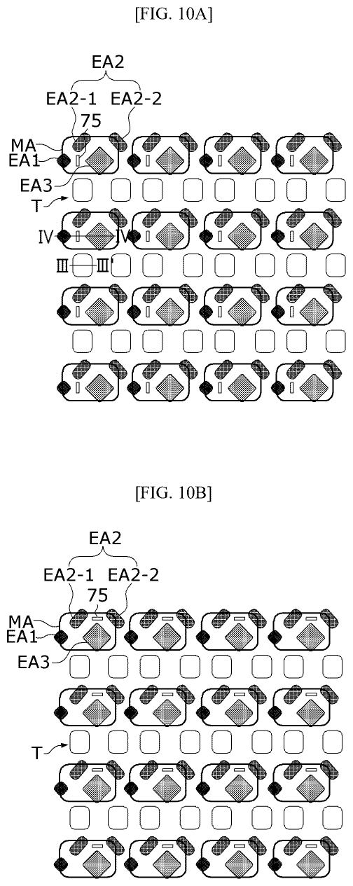

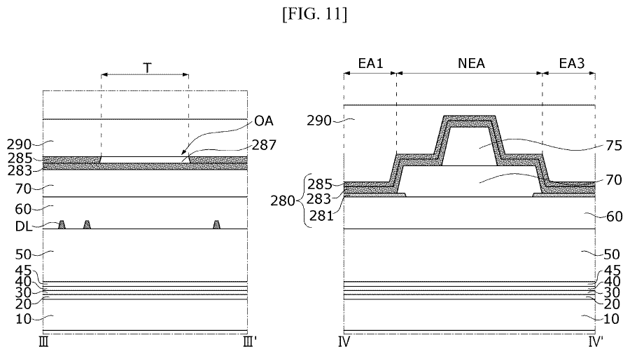

FIGS. 10A and 10B are plan views of a display panel according to a ninth embodiment of the present disclosure. FIG. 11 shows cross-sectional views along lines III-III′ and IV-IV′ of FIG. 10A.

The display panel according to the ninth embodiment can further include a plurality of spacers 75. The display panel according to the present embodiment can show the arrangement structure of the spacers 75 when the second emission area EA2 is disposed at one side of the first and third emission areas EA1 and EA3.

Referring to FIG. 11, a plurality of spacers 75 can be disposed in the shape of an island on the bank 70. The spacers 75 can be disposed to prevent sagging of a fine metal mask (FMM) that is used when forming a luminous layer disposed in each emission area EA.

Since the spacers 75 are formed by being patternized on the bank 70, the spacers 75 can cause diffraction of light entering from outside the display panel. Therefore, in the display panel of the present disclosure according to one embodiment, diffraction of light can be minimized by placing the spacers 75 to not overlap the transmission parts T.

A metal patterning layer 287 can be disposed on an intermediate layer 283. The metal patterning layer 287 can include a transmission part T therein. The metal patterning layer 287 can be disposed to form an opening OA of a second electrode 285.

A mask used when forming the metal patterning layer 287 can interfere with the spacer 75. Here, in the display panel of the present disclosure, the spacer 75 may not be disposed in the transmission part T. Accordingly, in the display panel of the present disclosure, interference with the spacer 75 can be prevented at a boundary of an opening of the mask used when forming the metal patterning layer 287.

Therefore, the spacer 75 of the present disclosure according to one embodiment may not overlap the transmission part T and the metal patterning layer 287 and can be disposed in the first driving circuit part MA. Meanwhile, the second active area AA2, which is a general active area, can be disposed regardless of the arrangement structure of the spacer 75 of the first active area AA1.

For example, referring to FIGS. 10A and 10B, the spacers 75 can be disposed in the first driving circuit part MA. Referring to FIG. 10A, the spacers 75 can be disposed between the first emission area EA1 and the third emission area EA3. Referring to FIG. 10B, the spacers 75 can be disposed between the second-first emission area EA2-1 and the second-second emission area EA2-2.

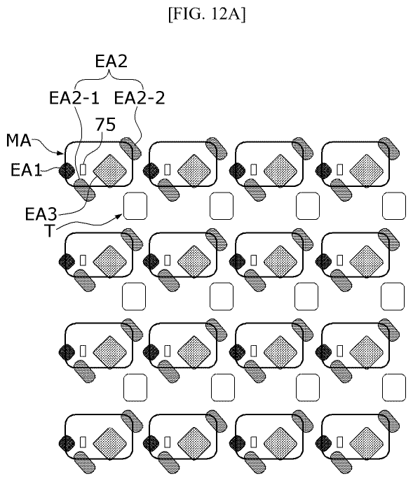

FIGS. 12A and 12B are plan views of a display panel 1 according to a tenth embodiment of the present disclosure.

The display panel according to the tenth embodiment can further include a plurality of spacers 75. The display panel according to the present embodiment can show the arrangement structure of the spacers 75 when the second-first and second-second emission areas EA2-1 and EA2-2 are disposed in the diagonal direction of the third emission area EA3.

Referring to FIGS. 12A and 12B, the spacers 75 can be disposed in the first driving circuit part MA.

Referring to FIG. 12A, the spacers 75 can be disposed between the first emission area EA1 and the third emission area EA3.

Referring to FIG. 12B, the spacers 75 can be disposed between the first emission area EA1 and the third emission area EA3 of two first pixel parts P adjacent to each other.

In the present disclosure, the arrangement structure of the spacers 75 in the first driving circuit part MA is not limited to that shown in FIGS. 10A, 10B, 12A, and 12B. In the present disclosure, the spacers 75 can be freely placed as long as they do not overlap the transmission part T and the metal patterning layer 287.

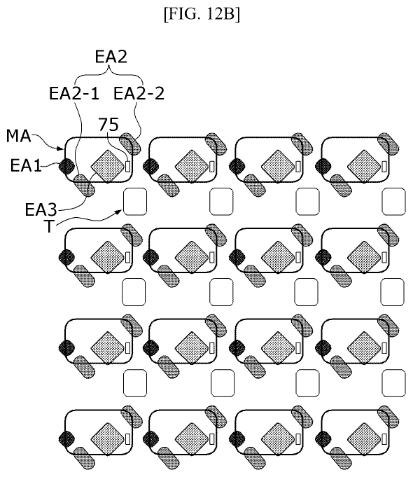

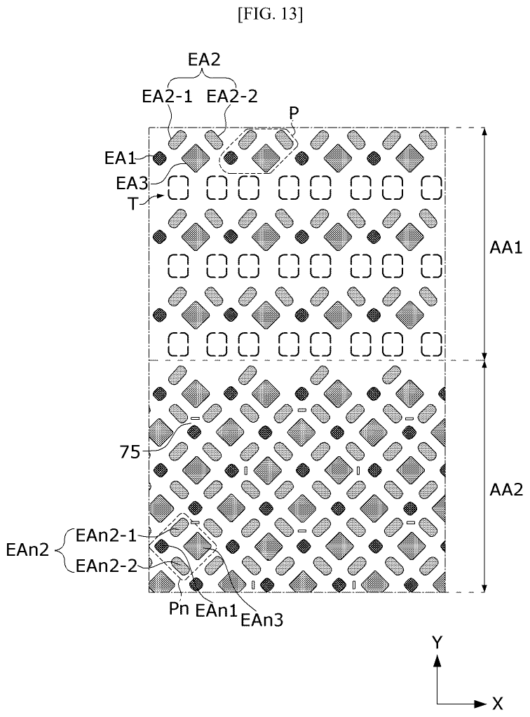

FIG. 13 is a plan view of a display panel according to an eleventh embodiment of the present disclosure. FIG. 13 is a plan view schematically illustrating a first active area AA1 and a second active area AA2.

Referring to FIG. 13, the spacers 75 can only be disposed in the second active area AA2 and may not be disposed in the first active area AA1. The first active area AA1 can be formed of a very small area throughout the display panel 1. In this way, even when the spacers 75 are not disposed in the first active area AA1, the FMM sagging issue may not occur in the first active area AA1.

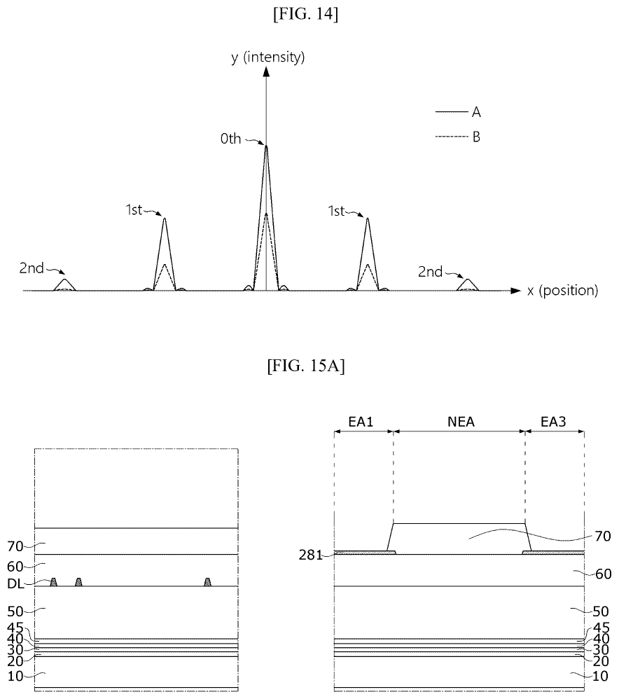

FIG. 14 is a PSF comparison graph according to the presence/absence of spacers in the first active area AA1.

Referring to FIG. 14, PSF values are different between a case in which the spacers 75 are disposed in the first active area AA1 and a case in which the spacers 75 are not disposed in the first active area AA1. A is the case in which the spacers 75 are not disposed in the first active area AA1, and B is the case in which the spacers 75 are disposed in the first active area AA1. In the display panel of the present disclosure according to the eleventh embodiment, by not placing the spacers 75 in the first active area AA1, diffraction of light can be minimized, and an effect of improving the PSF can be achieved.

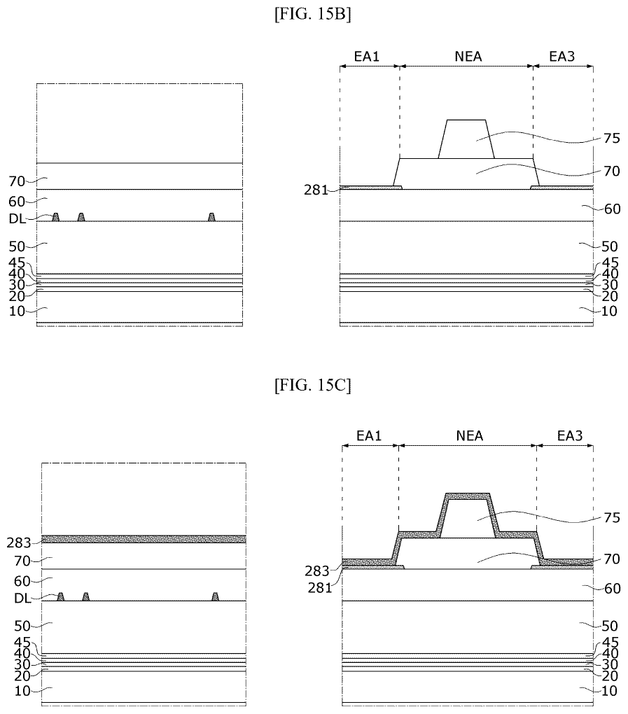

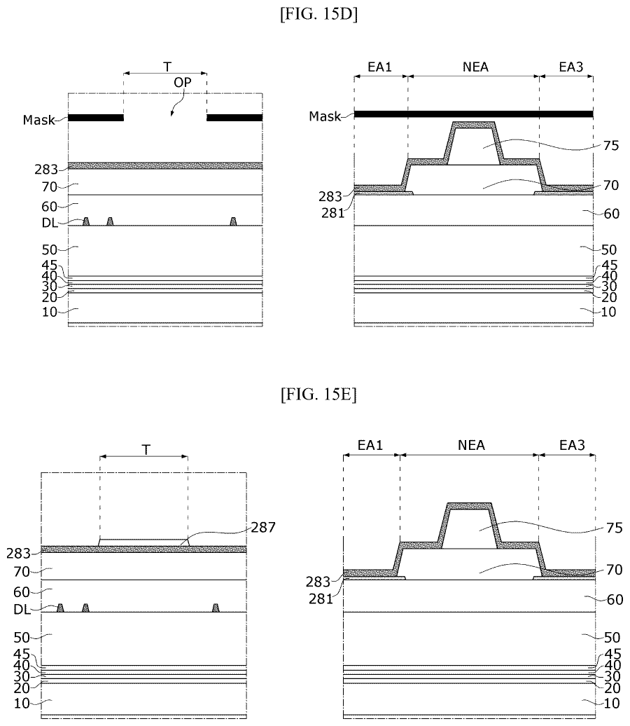

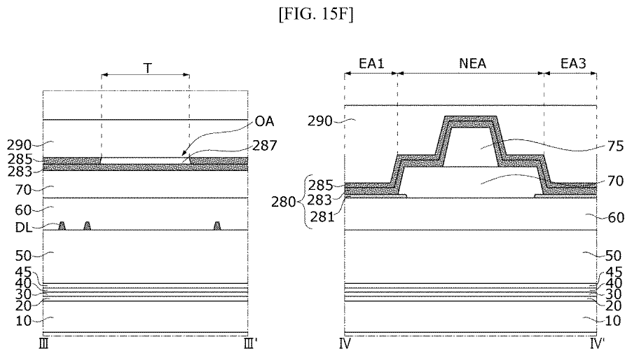

FIGS. 15A to 15F are process views of FIG. 11 according to an example of the present disclosure.

Referring to FIG. 15A, a buffer layer 20, an interlayer insulator 40, a gate insulator 30, a passivation layer 45, a first planarization layer 50, and a second planarization layer 60 can be sequentially formed on a front surface of a substrate 10. Various transistors and signal lines can be formed through a mask between the substrate 10 and the second planarization layer 60.

A first electrode 281 and a bank 70 can be sequentially formed on the second planarization layer 60.

The first electrode 281 can be formed on the second planarization layer 60 to correspond to each emission area EA through a mask.

The bank 70 can be formed on a top surface on the second planarization layer 60 through a mask and can expose a portion of the first electrode 281 corresponding to the emission area EA.

Referring to FIG. 15B, the spacer 75 can be formed on the bank 70. The spacer 75 may not be formed on the transmission part T.

Referring to FIG. 15C, the intermediate layer 283 can be formed on the first electrode 281, the bank 70, and the spacer 75. The intermediate layer 283 can include a luminous layer that corresponds to each emission area EA. The intermediate layer 283 can have a common layer, excluding the luminous layer, formed as a common mask.

Referring to FIG. 15D, a metal patterning layer material can be formed on the intermediate layer 283. Then, a metal patterning layer mask can be disposed to face the substrate 10.

The metal patterning layer mask can include a mask opening OP that corresponds to the transmission part T. An exposure process using the metal patterning layer mask can be performed. By not placing the spacer 75 on the transmission part T, interference between the mask opening OP of the metal patterning layer mask and the spacer 75 can be prevented in the display panel of the present disclosure.

Referring to FIG. 15E, the metal patterning layer 287 can be formed as an area that corresponds to the transmission part T through an etching process.

Referring to FIG. 15F, the second electrode 285 can be formed.

A material of the second electrode 285 can be sprayed to the top surface of the substrate 10. The second electrode 285 may not be formed on a surface of the metal patterning layer 287 due to a low probability of sticking to the surface of the metal patterning layer 287. Accordingly, the second electrode 285 can be formed on the intermediate layer 283 while excluding the transmission part T.

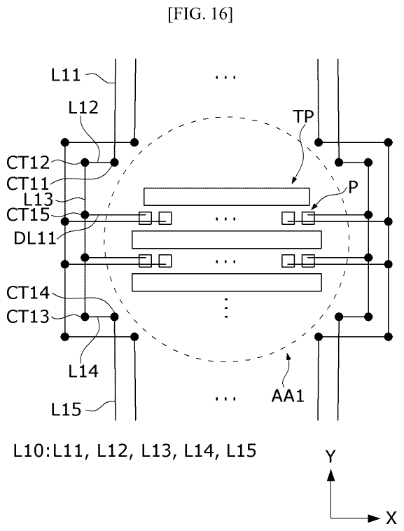

FIG. 16 is a schematic plan view of a display panel 1 according to a twelfth embodiment of the present disclosure.

Referring to FIG. 16, in the display panel 1 of the present disclosure according to the twelfth embodiment, a plurality of signal lines L10 can be disposed around a first active area AA1. The signal lines L10 according to the present embodiment can be disposed from the second active area AA2 to the inside of the first active area AA1 and may not overlap a transmission pattern area TP. The signal lines L10 can be disposed to overlap first pixel parts P. When the first pixel parts P are arranged in a plurality of rows in the row direction X, the transmission pattern area TP can be disposed between the first pixel parts P adjacent to each other in the column direction Y.

The signal lines L10 can extend from a non-active area NA and can be disposed inside the second active area AA2 and the first active area AA1 in order to be connected to first driving circuit parts of the first pixel parts P. For example, the signal lines L10 can include various signal lines such as a signal line for transmitting a signal to a camera or a sensor disposed in the first active area AA1, a data signal line, a gate signal line, or a power voltage line. The signal lines L10 according to the present embodiment can be data signal lines connected to data lines that intersect boundary portions between transmission parts in the previous embodiment. However, the display panel of the present disclosure is not limited thereto.

The signal lines L10 can include a first signal line L11, a second signal line L12, a third signal line L13, a fourth signal line L14, and a fifth signal line L15. The first to fifth signal lines L11, L12, L13, L14, and L15 can be connected through contact parts CT11, CT12, CT13, and CT14 at points of intersection of one another.

Specifically, the first signal line L11 advancing to the first active area AA1 can be formed in the column direction Y and can be electrically connected to the second signal line L12 formed in the row direction X through a first contact part CT11. The second signal line L12 can be electrically connected to the third signal line L13 formed in the column direction Y through a second contact part CT12. The third signal line L13 can be electrically connected to the fourth signal line L14 formed in the row direction X through a third contact part CT13. The fourth signal line L14 can be electrically connected to the fifth signal line L15 formed in the column direction Y through a fourth contact part CT14.

A plurality of data lines DL11 each corresponding to one of the first pixel parts P can be disposed on the first pixel parts P. The data lines DL11 corresponding to the first pixel parts P disposed in an arbitrary first column can be connected to one signal line L10. For example, a first pixel part disposed in an arbitrary first row and first column, a first pixel part disposed in an arbitrary second row and first column, . . . , and a first pixel part disposed in an arbitrary n-th row and first column can be connected to one signal line. However, the display panel of the present disclosure is not limited thereto. For example, a data line disposed across pixel parts disposed in an arbitrary first row can transmit a signal to the pixel parts disposed in the first row.

Each data line DL11 can be connected to the signal line L10 through a fifth contact part CT15. The data lines DL11 can be connected to the third signal line L13. However, the display panel of the present disclosure is not limited thereto. For example, any one data line DL11 can be connected to any one of the first to fifth signal lines L11, L12, L13, L14, and L15.

Each data line DL11 and the third signal line L13 can be disposed in different layers. Each data line DL11 and the third signal line L13 can be electrically connected through a contact hole formed in the fifth contact part CT15.

The transmission pattern area TP can be an area between first pixel parts P adjacent in the column direction Y. Signal lines may not be disposed in the transmission pattern area TP. In addition, the transmission pattern area TP can include all of the transmission part T, the first to third transmission parts T1, T2, and T3, and the first pattern including a plurality of first transmission parts T1 of the previous embodiments.

Accordingly, the display panel 1 according to the present embodiment can have an effect of enabling transmission parts having different transmittances to be freely designed in the transmission pattern area TP. In this way, the display panel 1 of the present disclosure can have an effect of improving image resolution of sensors by improving the PSF.

A display panel according to one embodiment of the present disclosure can include a substrate including a first active area including an emission area, a first transmission part, and a second transmission part and a second active area surrounding the first active area, a luminous element disposed on the substrate and including a first electrode overlapping the emission area and a second electrode facing the first electrode, and a signal line disposed between the first transmission part and the second transmission part, wherein the first transmission part has a higher transmittance than the second transmission part.

According to the display panel of the present disclosure according to one embodiment, the second electrode can have an opening that corresponds to the first transmission part.

According to the display panel of the present disclosure according to one embodiment, the display panel can further include a driving circuit part disposed between the substrate and the luminous element, the driving circuit part can include at least one transistor driving the luminous element and a connection electrode connecting the at least one transistor and the luminous element, and the first transmission part and the second transmission part may not overlap the driving circuit part when viewed from a plane and a cross-section of the display panel.

According to the display panel of the present disclosure according to one embodiment, the signal line can have a linear form between the first transmission part and the second transmission part.

According to the display panel of the present disclosure according to one embodiment, an area of the second transmission part can be larger than or equal to an area of the first transmission part.

According to the display panel of the present disclosure according to one embodiment, the first transmission part and the second transmission part can be alternately disposed in a row direction of the display panel.

According to the display panel of the present disclosure according to one embodiment, at least one signal line can be disposed on at least one of boundary portions between first transmission parts in a first pattern, and the first pattern and the second transmission part can be alternately disposed in the row direction.

According to the display panel of the present disclosure according to one embodiment, the first active area can further include a third transmission part having the same transmittance as the second transmission part and having a smaller area than the second transmission part, and the first to third transmission parts can be alternately disposed in the row direction.

According to the display panel of the present disclosure according to one embodiment, the first active area can include a plurality of first pixel parts, emission areas disposed in the first pixel parts can include a first emission area, a second emission area, and a third emission area of different colors, the second emission area can be branched into and include a second-first emission area and a second-second emission area with a connection pattern disposed therebetween, the first emission area and the third emission area can be disposed side by side in the row direction, and the second-first emission area and the second-second emission area can be disposed side by side in the row direction at one side of the first emission area and the third emission area in the column direction.

According to the display panel of the present disclosure according to one embodiment, the luminous element can further include a second-first luminous element that corresponds to the second-first emission area and a second-second luminous element that corresponds to the second-second emission area, and the second-first luminous element and the second-second luminous element can be connected to one driving transistor.

According to the display panel of the present disclosure according to one embodiment, the second emission area can emit green light.

According to the display panel of the present disclosure according to one embodiment, the second active area can further include an emission area, the display panel can further include an insulating layer disposed between the substrate and the luminous element, a bank disposed on the insulating layer and exposing each of the emission area of the first active area and the emission area of the second active area, and a spacer disposed on the bank, and the spacer can be disposed in the second active area without being disposed in the first active area.

A display panel according to one embodiment of the present disclosure can include a first active area including a first pixel part, a transmission pattern area, and a first driving circuit part disposed in the first pixel part while spaced from the transmission pattern area, a second active area surrounding the first active area and including a second pixel part and a second driving circuit part disposed in the second pixel part, and a substrate including the first and second active areas, wherein the first driving circuit part and the second driving circuit part can each include a plurality of transistors disposed on the substrate, and the transistors disposed in the first driving circuit part can be fewer in number than the transistors disposed in the second driving circuit part.

A display panel according to one embodiment of the present disclosure can have an effect of improving image resolution of sensors by improving a PSF.

Effects of the present disclosure are not limited to that mentioned above, and other unmentioned effects should be clearly understood by those of ordinary skill in the art to which the technical spirit of the present disclosure pertains from the content described herein.

Embodiments of the present disclosure (invention) have been described in more detail above with reference to the accompanying drawings, but the present invention is not necessarily limited to these embodiments and can be modified in various ways within the scope not departing from the technical spirit of the present invention.

Therefore, the embodiments disclosed in the present disclosure (invention) are for showing, instead of limiting, the technical spirit of the present invention, and the scope of the technical spirit of the present invention is not limited by the embodiments.

Therefore, the embodiments described above should be understood as illustrative, instead of limiting, in all aspects.

The protection scope of the present invention should be construed based on the scope of the claims, and all technical ideas within the scope equivalent thereto should be construed as belonging to the scope of rights of the present invention.

What is claimed is:

1. A display panel comprising:
a substrate including a first active area including an emission area, a first transmission part, and a second transmission part, and a second active area surrounding the first active area;
a luminous element disposed on the substrate, and including a first electrode overlapping the emission area and a second electrode facing the first electrode; and
a signal line disposed between the first transmission part and the second transmission part,
wherein the first transmission part has a higher transmittance than the second transmission part.

2. The display panel of claim 1, wherein the second electrode has an opening that corresponds to the first transmission part.

3. The display panel of claim 1, further comprising a driving circuit part disposed between the substrate and the luminous element,
wherein:
the driving circuit part includes at least one transistor configured to drive the luminous element, and a connection electrode connecting the at least one transistor and the luminous element;
the display panel has planes having a longitudinal direction and a width direction and a cross-section in a thickness direction; and
the first transmission part and the second transmission part do not overlap the driving circuit part when viewed from the planes and the cross-section of the display panel.

4. The display panel of claim 1, wherein the signal line has a linear form between the first transmission part and the second transmission part.

5. The display panel of claim 1, wherein a size of an area of the second transmission part is larger than or equal to a size of an area of the first transmission part.

6. The display panel of claim 1, wherein:
the display panel has a length in a row direction and a width in a column direction; and
the first transmission part and the second transmission part are alternately disposed in the row direction of the display panel.

7. The display panel of claim 1, wherein:
the display panel has a length in a row direction and a width in a column direction;
the first active area includes a first pattern including a plurality of first transmission parts;
at least one signal line is disposed on at least one of boundary portions between the plurality of first transmission parts in the first pattern; and
the first pattern and the second transmission part are alternately disposed in the row direction.

8. The display panel of claim 1, wherein:
the display panel has a length in a row direction and a width in a column direction;
the first active area further includes a third transmission part having the same transmittance as the second transmission part and having a smaller area size than the second transmission part; and
the first, second and third transmission parts are alternately disposed in the row direction.

9. The display panel of claim 1, wherein:
the first active area includes a plurality of first pixel parts;
emission areas disposed in the plurality of first pixel parts include a first emission area, a second emission area, and a third emission area of different colors;
the second emission area includes a second-first emission area and a second-second emission area with a connection pattern disposed therebetween;
the display panel has a length in a row direction and a width in a column direction;
the first emission area and the third emission area are disposed side by side in the row direction; and
the second-first emission area and the second-second emission area are disposed side by side in the row direction at one side of the first emission area and the third emission area in the column direction.

10. The display panel of claim 9, wherein:
the luminous element further includes a second-first luminous element that corresponds to the second-first emission area and a second-second luminous element that corresponds to the second-second emission area; and
the second-first luminous element and the second-second luminous element are connected to one driving transistor.

11. The display panel of claim 9, wherein the second emission area is configured to emit green light.

12. The display panel of claim 1, wherein:
the second active area includes an emission area;
the display panel further comprises an insulating layer disposed between the substrate and the luminous element, a bank disposed on the insulating layer and exposing each of the emission area of the first active area and the emission area of the second active area, and a spacer disposed on the bank; and
the spacer is disposed in the second active area without being disposed in the first active area.

13. A display panel comprising:
a first active area including a first pixel part, a transmission pattern area, and a first driving circuit part disposed in the first pixel part while being spaced apart from the transmission pattern area;
a second active area surrounding the first active area, and including a second pixel part and a second driving circuit part disposed in the second pixel part; and
a substrate including the first and second active areas,
wherein each of the first driving circuit part and the second driving circuit part includes a plurality of transistors disposed on the substrate, and
the plurality of transistors disposed in the first driving circuit part are fewer in number than the plurality of transistors disposed in the second driving circuit part.

14. The display panel of claim 13, wherein:
each of the first pixel part and the second pixel part includes an emission area;
the display panel further comprises an insulating layer disposed on the plurality of transistors of each of the first driving circuit part and the second driving circuit part, a bank disposed on the insulating layer and exposing each of an emission area of the first active area and an emission area of the second active area, and a spacer disposed on the bank; and
the spacer is disposed in the second active area without being disposed in the first active area.

15. The display panel of claim 13, wherein:
the first active area includes a plurality of first pixel parts;
the plurality of first pixel parts are disposed in a plurality of rows in a row direction of the display panel and a plurality of columns in a column direction of the display panel; and
the transmission pattern area is disposed in the row direction of the display panel between the plurality of first pixel parts adjacent to each other in the column direction of the display panel.

16. The display panel of claim 15, wherein the transmission pattern area of the first active area includes a first transmission part and a second transmission part having a lower transmittance than the first transmission part.

17. The display panel of claim 16, wherein:
the first pixel part includes an emission area;
the display panel further comprises a luminous element disposed on the substrate, and including a first electrode overlapping the emission area and a second electrode facing the first electrode; and
the second electrode has an opening that corresponds to the first transmission part.

18. The display panel of claim 16, wherein a size of an area of the second transmission part is larger than or equal to a size of an area of the first transmission part.

19. The display panel of claim 16, wherein:
the display panel has a length in a row direction and a width in a column direction; and
the first transmission part and the second transmission part are alternately disposed in the row direction of the display panel.

20. The display panel of claim 16, wherein:
the display panel has a length in a row direction and a width in a column direction;
the transmission pattern area further includes a third transmission part having a same transmittance as the second transmission part and having a smaller area size than the second transmission part; and
the first, second and third transmission parts are alternately disposed in the row direction.

21. The display panel of claim 16, further comprising at least one signal line connected to the first driving circuit part,
wherein the at least one signal line is disposed from the second active area to an inside of the first active area and does not overlap the transmission pattern area.

22. The display panel of claim 13, wherein:
the transmission pattern area of the first active area includes a first transmission part and a second transmission part having a lower transmittance than the first transmission part; and
the display panel further comprises at least one signal line disposed between the first transmission part and the second transmission part.

23. The display panel of claim 22, wherein the at least one signal line has a linear form.

24. A display panel comprising:
a substrate including a first active area including an emission area and a first transmission part, and a second active area surrounding the first active area;
a luminous element disposed on the substrate, and including a first electrode overlapping the emission area and a second electrode facing the first electrode; and
a driving circuit part configured to drive the luminous element,
wherein the second electrode and the driving circuit part do not overlap with the first transmission part.

25. The display panel of claim 24, wherein the first active area further includes a second transmission part overlapping with the second electrode but not overlapping with the driving circuit part.

26. The display panel of claim 25, wherein the first transmission part and the second transmission part are disposed alternatingly.
